(19) United States
(12) Patent Application Publication
(10) Pub. No.: US 2024/0012147 A1
(43) Pub. Date: Jan. 11, 2024

(54) IMAGING SYSTEM USING LIGHT SOURCE WITH TUNABLE ELECTRO-OPTICS

(71) Applicant: SiLC Technologies, Inc., Monrovia, CA (US)

(72) Inventors: Amir Ali Tavallaee, San Francisco, CA (US); Constanze Hantschmann, Potsdam (DE); Mehdi Asghari, La Canada Flintridge, CA (US); Ayan Chakrabarty, Azusa, CA (US); Sepehr Ahmadzadeh Benis, Los Angeles, CA (US)

(21) Appl. No.: 17/858,042

(22) Filed: Jul. 5, 2022

(51) Int. Cl. G01S 17/89; G01S 7/481; H01S 5/14

(52) U.S. Cl. CPC G01S 17/89; G01S 7/4814; H01S 5/143

(57) ABSTRACT

The imaging system includes a light source having a laser cavity. A light signal resonates in the laser cavity along an optical path that includes a tunable electro-optic configured to select wavelengths in multiple different wavelength bands. Electronics tune the electro-optic such the selection of wavelengths in the wavelength bands change in response to the tuning. The optical path includes a second optical component configured to select wavelengths in multiple different second wavelength bands. The output of the laser cavity has wavelengths that are common to one of the wavelength bands and one of the second wavelength bands.

### FIELD

The invention relates to light sources. In particular, the invention relates to light sources in imaging systems.

### BACKGROUND

Imaging systems such as LIDAR systems are being used in an increasing number of applications. These systems output a system output signal with a chirped frequency. The system output signals in these systems preferably have a narrow linewidth and high side-mode suppression at elevate chirp rates. The light sources that are available for use in these systems have not been able to effectively provide these features. As a result, there is a need light sources that are suitable for use in these systems.

### SUMMARY

An imaging system includes a light source having a laser cavity. A light signal resonates in the laser cavity along an optical path that includes a tunable electro-optic configured to select wavelengths in multiple different wavelength bands. Electronics tune the electro-optic such the selection of wavelengths in the wavelength bands change in response to the tuning. The optical path includes a second optical component configured to select wavelengths in multiple different second wavelength bands. The output of the laser cavity has wavelengths that are common to one of the wavelength bands and one of the second wavelength bands.

An embodiment of an imaging system includes an external cavity laser with a laser cavity that is partially defined by a tunable optical grating. The tunable optical grating reflects light signals in multiple different reflection bands. Electronics are configured to tune the optical grating such wavelengths of light in the reflection bands changes in response to the tuning. In some instances, the imaging system includes a second optical grating that reflects light signals in multiple different second reflection bands. Additionally, the output from the laser cavity has wavelengths that are shared by one of the reflection bands and one of the second reflection bands.

An embodiment of an imaging system includes an external cavity laser with a laser cavity in which a light signal resonates along a pathway that includes waveguides and a tunable ring resonator. The tunable ring resonator couples light traveling one of the waveguides in multiple different transmission bands from the waveguide into the tunable ring resonator. Electronics tune the tunable ring resonator such that wavelengths of light in the transmission bands changes in response to the tuning. In some instances, the pathway includes a second ring resonator that couples light traveling along one of the waveguides in multiple different second transmission bands from the waveguide into the second ring resonator. Additionally, the output from the laser cavity has wavelengths that are shared by one of the transmission bands and one of the second transmission bands.

### BRIEF DESCRIPTION OF THE FIGURES

FIG. 1A illustrates an imaging system that includes a chip with a photonic circuit.

FIG. 1B illustrates another embodiment of an imaging system that includes a photonic circuit chip.

FIG. 1C illustrates another embodiment of an imaging system that includes a photonic circuit chip.

FIG. 2 is a schematic of an imaging system that includes multiple different cores on a chip.

FIG. 3A through FIG. 3B illustrate an example of a processing component that is suitable for use as the processing component in a LIDAR system constructed according to FIG. 1A and FIG. 1B. FIG. 3A is a schematic of an example of a suitable optical-to-electrical assembly for use in the processing component.

FIG. 3B provides a schematic of the relationship between electronics and the optical-to-electrical assembly of FIG. 3A.

FIG. 3C illustrates the frequency of a signal output from the imaging system over time.

FIG. 3D provides a schematic of the relationship between electronics and the optical-to-electrical assembly of FIG. 3A.

FIG. 3E is a schematic of another relationship between sensors in the optical-to-electrical assembly from FIG. 3A and electronics in the LIDAR system.

FIG. 4 is a cross section of a silicon-on-insulator wafer.

FIG. 5A and FIG. 5B illustrate an example of an optical switch that includes cascaded Mach-Zehnder interferometers. FIG. 5A is a topview of the optical switch.

FIG. 5B is a cross section of the optical switch shown in FIG. 5A taken along the line labeled B in FIG. 5A.

FIG. 6 illustrates the LIDAR system of FIG. 2 modified to have multiple signal directors that each receives LIDAR output signals from a different core.

FIG. 7 illustrates the LIDAR system of FIG. 2 where a light source is located external to the chip.

FIG. 8 illustrates a portion of a LIDAR chip that includes a reference waveguide used in conjunction with a beam dump.

FIG. 9 is a schematic of a topview of a portion of a LIDAR chip that includes a light source this suitable for use in the imaging systems.

FIG. 10A is an example reflection profile for an optical grating that can serve as a first optical grating in a light source.

FIG. 10B is an example reflection profile for an optical grating that can serve as a second optical grating in a light source.

FIG. 10C is a graph showing the reflection profiles for the first optical grating and the second optical grating.

FIG. 10D is a graph showing the reflection profiles for the first optical grating and the second optical grating.

FIG. 11 is a schematic of a topview of a portion of a LIDAR chip that includes a light source this suitable for use in the imaging systems.

FIG. 12A is an example reflection profile for an optical grating that can serve as a first optical grating in a light source.

FIG. 12B is an example reflection profile for an optical grating that can serve as a second optical grating in a light source.

FIG. 12C is a graph showing the reflection profiles for the first optical grating and the second optical grating.

FIG. 12D is a graph showing the reflection profiles for the first optical grating and the second optical grating.

FIG. 13A through FIG. 13D illustrates an example of an interface between a gain medium chip and a platform such as a silicon-on-insulator chip.

FIG. 13B is a cross section of the interface shown in FIG. 13A taken along the line labeled B.

FIG. 13C is a cross section of the interface taken along a line extending between the brackets labeled C in FIG. 13A.

FIG. 13D is a cross section of the interface taken along a line extending between the brackets labeled D in FIG. 13A.

FIG. 13E is a cross section of the interface of FIG. 13A taken along a line extending between the brackets labeled D in FIG. 13A.

FIG. 14A is a perspective view of an optical grating.

FIG. 14B is a cross section of the optical grating shown in FIG. 14A taken along the line labeled B in FIG. 14A.

FIG. 14C is a topview of a portion of a waveguide that includes an optical grating.

FIG. 15 is a topview of a portion of a waveguide that includes a spiral waveguide.

### DESCRIPTION

The imaging system includes a light source having a laser cavity. A light signal resonates in the laser cavity along an optical path that includes a tunable electro-optic configured to select wavelengths in multiple different wavelength bands. The system includes electronics that tune the electro-optic such the selection of wavelengths in the wavelength bands change in response to the tuning. The optical path can include a second electro-optic configured to select wavelengths in multiple different second wavelength bands. Examples of electro-optics that are suitable for use as the tunable electro-optic and/or the second electro-optic include, but are not limited to, optical gratings and a ring resonator. The output of the laser cavity has wavelengths that are common to one of the wavelength bands and one of the second wavelength bands. The presence of the tunable electro-optic inside of the laser cavity can provide faster chirp rates for the output of the laser cavity while retaining narrow linewidth and high side-mode suppression.

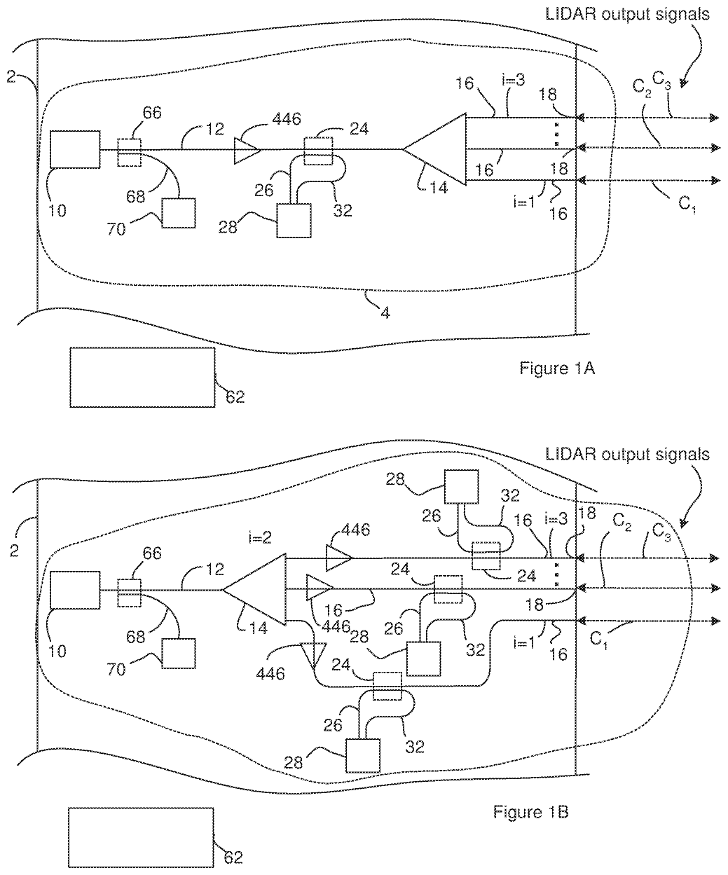

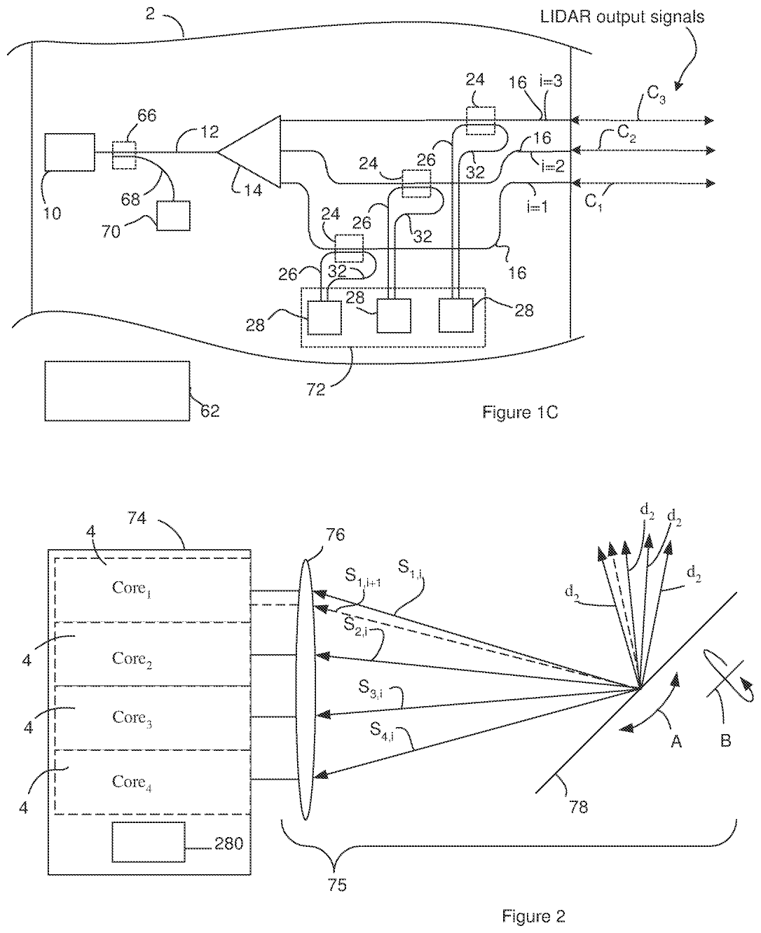

FIG. 1A is a schematic of a portion of a LIDAR system that includes a LIDAR chip 2. FIG. 1A includes a topview of a portion of the LIDAR chip 2. The LIDAR chip includes a LIDAR core 4. The LIDAR core 4 includes a photonic integrated circuit.

The LIDAR core 4 can include a light source 10 that outputs an outgoing LIDAR signal. The LIDAR core includes a utility waveguide 12 that receives the outgoing LIDAR signal from the light source 10. The utility waveguide 12 carries the outgoing LIDAR signal to a signal directing component 14. The signal directing component 14 can be operated by electronics so as direct light from the outgoing LIDAR signal to one of multiple different alternate waveguides 16. There are N alternate waveguides and each of the alternate waveguides 16 is associated with an alternate waveguide index i where i has a value from 1 to N. Suitable values of N include, but are not limited to, values less than 128, 64, or 32 and/or greater than or equal to 1, 8, or 16. In one example, N is in a range of 1 to 128.

Each of the alternate waveguides 16 can receive the outgoing LIDAR signal from the signal directing component 14. When any of the alternate waveguides 16 receives the outgoing LIDAR signal, the alternate waveguides 16 serves an active waveguide and carries the outgoing LIDAR signal to a port 18 through which the outgoing LIDAR signal can exit from the LIDAR chip and serve as a LIDAR output signal. Accordingly, the outgoing LIDAR signal is output from the active waveguide.

Light signals that result from the outgoing LIDAR signal being directed to the alternate waveguide 16 with alternate waveguide index i are classified as light signals carrying channel (Cᵢ). Accordingly, each of the LIDAR output signals is associated with a different one of the alternate waveguide indices channel index i=1 through N. For instance, the path of the LIDAR output signal that carries the channel with alternate waveguide index 2 is labeled C₂ in FIG. 1A. For the purposes of illustration, the LIDAR system is shown as generating three LIDAR output signals (N=3) labeled C₁ through C₃. Each of the different LIDAR output signals can carry a different channel, however, each of the different channels can carry the same selections of wavelength(s) or substantially the same selections of wavelength(s).

A LIDAR input signal returns to the LIDAR chip such that a LIDAR input signal carrying channel Cᵢ enters the alternate waveguide 16 that is associated with the same alternate waveguide index i. As a result, LIDAR input signals carrying different channels are directed to different alternate waveguides. The portion of the LIDAR input signal that enters an alternate waveguide 16 serves as an incoming LIDAR signal. As a result, the alternate waveguide that receives the incoming LIDAR signal can guides an outgoing LIDAR signal while also guiding the incoming LIDAR signal in the opposite direction. The alternate waveguide 16 that receives the incoming LIDAR signal carries the incoming LIDAR signal to the signal directing component 14. The signal directing component 14 outputs the incoming LIDAR signal on the utility waveguide 12.

The alternate waveguide 16 carries the incoming LIDAR signal to a splitter 24 that moves a portion of the incoming LIDAR signal from the alternate waveguide 16 onto a comparative waveguide 26 as a comparative signal. The comparative waveguide 26 carries the comparative signal to a processing component 28 for further processing. Suitable splitters 24 include, but are not limited to, optical couplers, y-junctions, and MMIs. In some instances, the splitter 24 is configured such that the power of the incoming LIDAR signal is divided evenly or substantially evenly between the utility waveguide 12 and the comparative waveguide 26.

The utility waveguide 12 also carries the outgoing LIDAR signal to a splitter 24. The splitter 24 moves a portion of the outgoing LIDAR signal from the utility waveguide 12 onto a reference waveguide 32 as a reference signal. The reference waveguide 32 carries the reference signal to the processing component 28 for further processing.

As will be described in more detail below, the processing component 28 combines the comparative signal with the reference signal to form a composite signal that carries LIDAR data for a sample region on the field of view. Accordingly, the composite signal can be processed so as to extract LIDAR data (radial velocity and/or distance between a LIDAR system and an object external to the LIDAR system) for the sample region.

The LIDAR chip can include a control branch for controlling operation of the light source 10. The control branch includes a directional coupler 66 that moves a portion of the outgoing LIDAR signal from the utility waveguide 12 onto a control waveguide 68. The coupled portion of the outgoing LIDAR signal serves as a tapped signal. Although FIG. 1A illustrates a directional coupler 66 moving the portion of the outgoing LIDAR signal onto the control waveguide 68, other signal-tapping components can be used to move a portion of the outgoing LIDAR signal from the utility waveguide 12 onto the control waveguide 68. Examples of suitable signal tapping components include, but are not limited to, y-junctions, and MMIs.

The control waveguide 68 carries the tapped signal to control components 70. The control components can be in electrical communication with electronics 62. Although FIG. 1A illustrates the electronics as a component that is separate from the processing component(s) 28, a portion of the electronics can be included in each of the processing component(s) 28. During operation, the electronics 62 can adjust the frequency of the outgoing LIDAR signal in response to output from the control components. An example of a suitable construction of control components is provided in U.S. patent application Ser. No. 15/977,957, filed on 11 May 2018, entitled “Optical Sensor Chip,” and incorporated herein in its entirety.

The incoming LIDAR signal passes through the signal directing component 14. The signal directing component 14 may be a source of optical loss. This source of optical loss can be removed by moving a portion of the incoming LIDAR signal that serves as the comparative signal onto the comparative waveguide 26 before the incoming LIDAR signal reaches the signal directing component 14. As an example, FIG. 1B illustrates the LIDAR chip of FIG. 1A modified such that a splitter 24 is located along each of the alternate waveguides 16 between the signal directing component 14 and the port 18. As a result, the comparative signal is extracted from the alternate waveguide 16 before the incoming LIDAR signal reaches the signal directing component 14.

A comparison of FIG. 1A and FIG. 1B shows that the LIDAR chip of FIG. 1B requires more processing components 28 than the LIDAR chip of FIG. 1A. As will become evident below, increasing the required number of processing components 28 increases the number of Analog-to-Digital Converters required by the LIDAR system. However, a common processing component 28 can be used to reduce the number of Analog-to-Digital Converters. As an example, FIG. 1C illustrates the LIDAR chip of FIG. 1B modified such that each of the comparative waveguides 26 carries one of the comparative signals to a common processing component 72. Additionally, each of the reference waveguide 32 carries one of the reference signals to the common processing component 72.

A LIDAR system can include a LIDAR chip with multiple LIDR cores 4. As an example, FIG. 2 illustrates a LIDAR chip that includes multiple different cores. The cores are each labeled coreₖ where k represents a core index k. Each of the LIDAR cores can be constructed as disclosed in the context of FIG. 1A through FIG. 1C or can have an alternate construction. Each of the LIDAR cores outputs a different LIDAR output signal. The LIDAR output signal output from the cores labeled coreₖ can be represented by S_{k,i} where i represents the channel index. As a result, S_{k,i} is function of the alternate waveguide index i and the core index k. As an example, the LIDAR output signal represented by S_{k,i} is output from coreₖ and was received by alternate waveguide index i. Accordingly, the LIDAR output signal represented by S_{k,i} is output from coreₖ and carries channel G.

The LIDAR system can include an optical component assembly 75 that receives the LIDAR output signals from different cores and outputs system output signals that each includes, consists of, or consists essentially of light from a different one of the LIDAR output signals. The optical component assembly 75 can be operated by electronics 280 so as to steer the system output signals to different sample regions in the LIDAR system's field of view.

FIG. 2 illustrates an optical component assembly 75 that includes signal director 76 that receives each of the LIDAR output signal. The signal director 76 changes the direction that at least a portion of the LIDAR output signals are traveling and outputs each of the LIDAR output signal as a re-directed LIDAR output signal. Suitable signal directors 76 include, but are not limited to, convex lenses and concave mirrors. The optical component assembly 75 includes one or more beam steering components 78 that receive the re-directed LIDAR output signals output from the signal director 76 as system output signals. The direction that the system output signals travel away from the LIDAR system is labeled d₂ in FIG. 2. The electronics can operate the one or more beam steering components 78 so as to steer the each of the system output signal to different sample regions in a field of view. As is evident from the arrows labeled A and B in FIG. 2, the one or more beam steering components 78 can be configured such that the electronics can steer the system output signals in one dimension or in two dimensions. As a result, the one or more beam steering components 78 can function as a beam-steering mechanism that is operated by the electronics so as to steer the system output signals within the field of view of the LIDAR system. Suitable beam steering components 78 include, but are not limited to, movable mirrors, MEMS mirrors, optical phased arrays (OPAs), optical gratings, and actuated optical gratings. In some instances, the signal director 76 and/or the one or more beam steering components 78 are configured to operate on the system output signals such that the system output signals are collimated or substantially collimated as they travel away from the LIDAR system. Additionally or alternately, the LIDAR system can include one or more collimating optical components (not illustrated) that operate on the LIDAR output signals, re-directed LIDAR output signals, and/or the system output signals such that the system output signals are collimated or substantially collimated as they travel away from the LIDAR system.

The system output signals can be reflected by an object located outside of the LIDAR system. All or a portion of the reflected light from a system output signal can return to the LIDAR system as a system return signal. Each of the system return signals is received at the one or more beam steering components 78. The one or more beam steering components 78 output at least a portion of each of the system return signals as a returned signal. The returned signals are each received at the signal director 76. The signal director 76 outputs at least a portion of each one of the returned signals as a LIDAR input signal. Each of the different LIDAR input signals is received by a different one of the cores 4. Each of the LIDAR input signals includes or consists of light from the LIDAR output signal that was output from the core that receives the LIDAR input signal. Additionally, the LIDAR input signal received at an alternate waveguide includes or consists of the light from the LIDAR output signal that was output from the same alternate waveguide.

The one or more signal directors 76 can change the direction that a LIDAR output signal travels away from the one or more signal directors 76 such that the direction of a LIDAR output signal is different from the resulting re-directed LIDAR output signal. In some instances, the one or more signal directors 76 are selected such that all or a portion of the re-directed LIDAR output signal travel away from the one or more signal directors 76 in non-parallel directions. As an example, in FIG. 2, the one or more signal directors 76 is a lens and each of the different LIDAR output signals is incident on the lens at a different angle of incidence. As a result, the re-directed LIDAR output signals each travels away from the signal director 76 in a different direction. Further, the re-directed LIDAR output signals travel away from the signal director 76 in non-parallel directions. As is evident from FIG. 2, the different directions of the system output signals can result in the system output signals traveling away from the LIDAR system in different directions. In some instances, the system output signals travel away from the LIDAR system in non-parallel directions.

Operating the signal directing component 14 on a core can change where the LIDAR output signal is received by the one or more signal directors 76 and can accordingly change the direction that the system output signal that originates from that core travels away from the LIDAR system. As an example, the dashed line in FIG. 2 illustrates the result of operating the signal directing component 14 on core₁ such that the core outputs the LIDAR output signal represented by S_{k,i+1} rather than the LIDAR output signal represented by S_{k,i}. As is evident from FIG. 2, this operation of the signal directing component 14 changes the direction that the system output signal output from core₁ travels away from the LIDAR system. As a result, the electronics can operate the signal directing components 14 on different cores so as to steer the system output signals within the LIDAR system's field of view. Accordingly, the electronics can operate the signal directing components 14 on different cores and/or the one or more beam steering components 78 so as to steer the system output signals within the LIDAR system's field of view. A suitable method of operating the signal directing components 14 on different cores and/or the one or more beam steering components 78 so as to steer the system output signals to different sample regions within the LIDAR system's field of view is disclosed in U.S. patent application Ser. No. 17/580,623, filed on Jan. 20, 2022, entitled “Imaging System Having Multiple Cores,” and incorporated herein in its entirety.

The optical component assembly 75 can have configurations other than the configuration shown in FIG. 2. For instance, the one or more beam steering components 78 can be positioned between the signal director 76 and the LIDAR chip. Additionally, the optical component assembly 75 can include optical components that are not illustrated. For instance, the optical component assembly 75 can include one or more lenses configured to increase collimation of the LIDAR output signals and/or other signals derived from the LIDAR output signals and/or that include light from the LIDAR output signals.

The wavelength of the LIDAR output signal output from different cores can be same or different. As a result, the light source on different cores can be configured to output an outgoing light signal that each has a selection of wavelength that is different, the same or substantially the same. Accordingly, the selection of wavelengths in different system output signals can be different, the same or substantially the same.

All or a portion of the electronics 62 associated with different cores can optionally be consolidated in the electronics 280 illustrated in FIG. 2. The consolidated electronics 280 can be positioned on the LIDAR chip or can be external to the LIDAR chip. The consolidated electronics 280 can collect or generate the LIDAR data results from different cores, and/or can coordinate the LIDAR data results from different cores so as to assemble LIDAR data results for the LIDAR system's field of view.

Although FIG. 2 illustrates four cores on the LIDAR chip, the LIDAR chip can include one, two, or more than two cores. Suitable numbers of cores on the LIDAR chip, include, but are not limited to, numbers greater than or equal to 2, 4, or 6 and/or less than 32, 64, or 128.

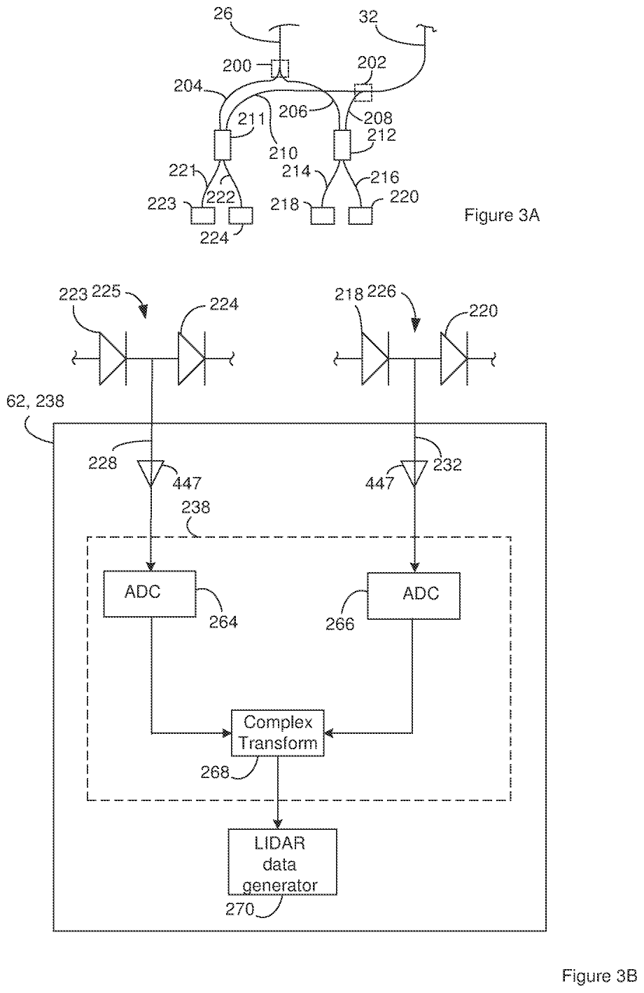

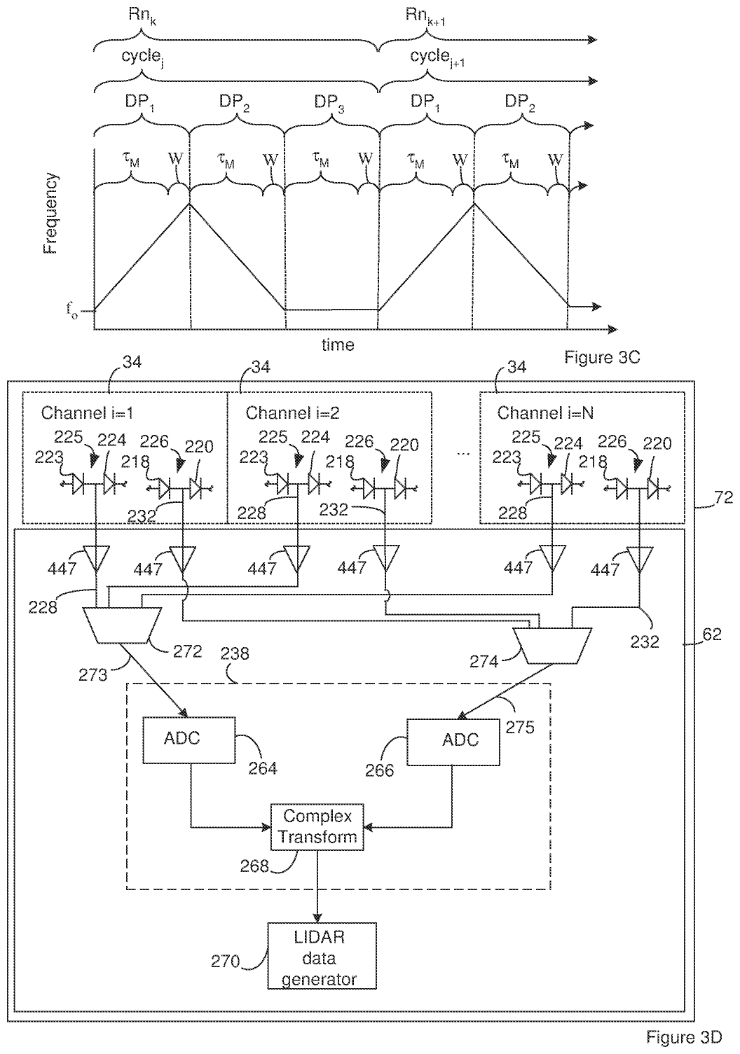

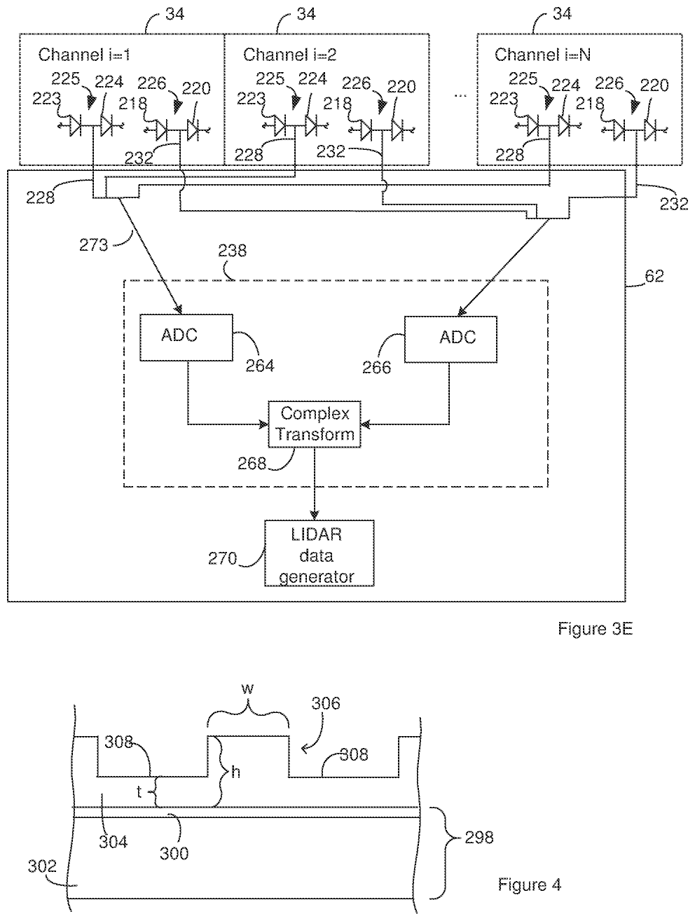

FIG. 3A through FIG. 3B illustrate an example of a processing component that is suitable for use as the processing component 28 in a LIDAR system constructed according to FIG. 1A and FIG. 1B. The processing component includes an optical-to-electrical assembly configured to convert the light signals to electrical signals. FIG. 3A is a schematic of an example of a suitable optical-to-electrical assembly that includes a first splitter 200 that divides the comparative signal received from the comparative waveguide 26 onto a first comparative waveguide 204 and a second comparative waveguide 206. The first comparative waveguide 204 carries a first portion of the comparative signal to a light combiner 211. The second comparative waveguide 206 carries a second portion of the comparative signal to a second light combiner 212.

The processing component of FIG. 2A also includes a second splitter 202 that divides the reference signal received from the reference waveguide 32 onto a first reference waveguide 210 and a second reference waveguide 208. The first reference waveguide 210 carries a first portion of the reference signal to the light combiner 211. The second reference waveguide 208 carries a second portion of the reference signal to the second light combiner 212.

The second light combiner 212 combines the second portion of the comparative signal and the second portion of the reference signal into a second composite signal. Due to the difference in frequencies between the second portion of the comparative signal and the second portion of the reference signal, the second composite signal is beating between the second portion of the comparative signal and the second portion of the reference signal. The first composite signal and the second composite signal are each an example of a composite signal.

The second light combiner 212 also splits the resulting second composite signal onto a first auxiliary detector waveguide 214 and a second auxiliary detector waveguide 216. The first auxiliary detector waveguide 214 carries a first portion of the second composite signal to a first auxiliary light sensor 218 that converts the first portion of the second composite signal to a first auxiliary electrical signal. The second auxiliary detector waveguide 216 carries a second portion of the second composite signal to a second auxiliary light sensor 220 that converts the second portion of the second composite signal to a second auxiliary electrical signal. Examples of suitable light sensors include germanium photodiodes (PDs), and avalanche photodiodes (APDs).

In some instances, the second light combiner 212 splits the second composite signal such that the portion of the comparative signal (i.e. the portion of the second portion of the comparative signal) included in the first portion of the second composite signal is phase shifted by 180° relative to the portion of the comparative signal (i.e. the portion of the second portion of the comparative signal) in the second portion of the second composite signal but the portion of the reference signal (i.e. the portion of the second portion of the reference signal) in the second portion of the second composite signal is not phase shifted relative to the portion of the reference signal (i.e. the portion of the second portion of the reference signal) in the first portion of the second composite signal. Alternately, the second light combiner 212 splits the second composite signal such that the portion of the reference signal (i.e. the portion of the second portion of the reference signal) in the first portion of the second composite signal is phase shifted by 180° relative to the portion of the reference signal (i.e. the portion of the second portion of the reference signal) in the second portion of the second composite signal but the portion of the comparative signal (i.e. the portion of the second portion of the comparative signal) in the first portion of the second composite signal is not phase shifted relative to the portion of the comparative signal (i.e. the portion of the second portion of the comparative signal) in the second portion of the second composite signal. Examples of suitable light sensors include germanium photodiodes (PDs), and avalanche photodiodes (APDs).

The first light combiner 211 combines the first portion of the comparative signal and the first portion of the reference signal into a first composite signal. Due to the difference in frequencies between the first portion of the comparative signal and the first portion of the reference signal, the first composite signal is beating between the first portion of the comparative signal and the first portion of the reference signal.

The light combiner 211 also splits the first composite signal onto a first detector waveguide 221 and a second detector waveguide 222. The first detector waveguide 221 carries a first portion of the first composite signal to a first light sensor 223 that converts the first portion of the second composite signal to a first electrical signal. The second detector waveguide 222 carries a second portion of the second composite signal to a second light sensor 224 that converts the second portion of the second composite signal to a second electrical signal. Examples of suitable light sensors include germanium photodiodes (PDs), and avalanche photodiodes (APDs).

In some instances, the light combiner 211 splits the first composite signal such that the portion of the comparative signal (i.e. the portion of the first portion of the comparative signal) included in the first portion of the composite signal is phase shifted by 180° relative to the portion of the comparative signal (i.e. the portion of the first portion of the comparative signal) in the second portion of the composite signal but the portion of the reference signal (i.e. the portion of the first portion of the reference signal) in the first portion of the composite signal is not phase shifted relative to the portion of the reference signal (i.e. the portion of the first portion of the reference signal) in the second portion of the composite signal. Alternately, the light combiner 211 splits the composite signal such that the portion of the reference signal (i.e. the portion of the first portion of the reference signal) in the first portion of the composite signal is phase shifted by 180° relative to the portion of the reference signal (i.e. the portion of the first portion of the reference signal) in the second portion of the composite signal but the portion of the comparative signal (i.e. the portion of the first portion of the comparative signal) in the first portion of the composite signal is not phase shifted relative to the portion of the comparative signal (i.e. the portion of the first portion of the comparative signal) in the second portion of the composite signal.

When the second light combiner 212 splits the second composite signal such that the portion of the comparative signal in the first portion of the second composite signal is phase shifted by 180° relative to the portion of the comparative signal in the second portion of the second composite signal, the light combiner 211 also splits the composite signal such that the portion of the comparative signal in the first portion of the composite signal is phase shifted by 180° relative to the portion of the comparative signal in the second portion of the composite signal. When the second light combiner 212 splits the second composite signal such that the portion of the reference signal in the first portion of the second composite signal is phase shifted by 180° relative to the portion of the reference signal in the second portion of the second composite signal, the light combiner 211 also splits the composite signal such that the portion of the reference signal in the first portion of the composite signal is phase shifted by 180° relative to the portion of the reference signal in the second portion of the composite signal.

The first reference waveguide 210 and the second reference waveguide 208 are constructed to provide a phase shift between the first portion of the reference signal and the second portion of the reference signal. For instance, the first reference waveguide 210 and the second reference waveguide 208 can be constructed so as to provide a 90-degree phase shift between the first portion of the reference signal and the second portion of the reference signal. As an example, one reference signal portion can be an in-phase component and the other a quadrature component. Accordingly, one of the reference signal portions can be a sinusoidal function and the other reference signal portion can be a cosine function. In one example, the first reference waveguide 210 and the second reference waveguide 208 are constructed such that the first reference signal portion is a cosine function and the second reference signal portion is a sine function. Accordingly, the portion of the reference signal in the second composite signal is phase shifted relative to the portion of the reference signal in the first composite signal, however, the portion of the comparative signal in the first composite signal is not phase shifted relative to the portion of the comparative signal in the second composite signal.

The first light sensor 223 and the second light sensor 224 can be connected as a balanced detector and the first auxiliary light sensor 218 and the second auxiliary light sensor 220 can also be connected as a balanced detector. The balanced detector(s) serve as light sensors that convert a light signal to an electrical signal. FIG. 3B provides a schematic of the relationship between the electronics, the first light sensor 223, the second light sensor 224, the first auxiliary light sensor 218, and the second auxiliary light sensor 220. The symbol for a photodiode is used to represent the first light sensor 223, the second light sensor 224, the first auxiliary light sensor 218, and the second auxiliary light sensor 220 but one or more of these sensors can have other constructions. In some instances, all of the components illustrated in the schematic of FIG. 3B are included on the LIDAR chip. In some instances, the components illustrated in the schematic of FIG. 3B are distributed between the LIDAR chip and electronics located off of the LIDAR chip.

The electronics connect the first light sensor 223 and the second light sensor 224 as a first balanced detector 225 and the first auxiliary light sensor 218 and the second auxiliary light sensor 220 as a second balanced detector 226. In particular, the first light sensor 223 and the second light sensor 224 are connected in series. Additionally, the first auxiliary light sensor 218 and the second auxiliary light sensor 220 are connected in series. The serial connection in the first balanced detector is in communication with a first data line 228 that carries the output from the first balanced detector as a first data signal. The serial connection in the second balanced detector is in communication with a second data line 232 that carries the output from the second balanced detector as a second data signal. The first data line and the second data line are each an example of a data line. The first data signal is an electrical data signal that carries a representation of the first composite signal and the second data signal is an electrical data signal that carries a representation of the second composite signal. Accordingly, the first data signal includes a contribution from a first waveform and a second waveform and the second data signal is a composite of the first waveform and the second waveform. The portion of the first waveform in the first data signal is phase-shifted relative to the portion of the first waveform in the first data signal but the portion of the second waveform in the first data signal being in-phase relative to the portion of the second waveform in the first data signal. For instance, the second data signal includes a portion of the reference signal that is phase shifted relative to a different portion of the reference signal that is included the first data signal. Additionally, the second data signal includes a portion of the comparative signal that is in-phase with a different portion of the comparative signal that is included in the first data signal. The first data signal and the second data signal are beating as a result of the beating between the comparative signal and the reference signal, i.e. the beating in the first composite signal and in the second composite signal.

The electronics 62 includes a transform mechanism 238 configured to perform a mathematical transform on the first data signal and the second data signal. For instance, the mathematical transform can be a complex Fourier transform with the first data signal and the second data signal as inputs. Since the first data signal is an in-phase component and the second data signal its quadrature component, the first data signal and the second data signal together act as a complex data signal where the first data signal is the real component and the second data signal is the imaginary component of the input.

The transform mechanism 238 includes a first Analog-to-Digital Converter (ADC) 264 that receives the first data signal from the first data line 228. The first Analog-to-Digital Converter (ADC) 264 converts the first data signal from an analog form to a digital form and outputs a first digital data signal. The transform mechanism 238 includes a second Analog-to-Digital Converter (ADC) 266 that receives the second data signal from the second data line 232. The second Analog-to-Digital Converter (ADC) 266 converts the second data signal from an analog form to a digital form and outputs a second digital data signal. The first digital data signal is a digital representation of the first data signal and the second digital data signal is a digital representation of the second data signal. Accordingly, the first digital data signal and the second digital data signal act together as a complex signal where the first digital data signal acts as the real component of the complex signal and the second digital data signal acts as the imaginary component of the complex data signal.

The transform mechanism 238 includes a transform component 268 that receives the complex data signal. For instance, the transform component 268 receives the first digital data signal from the first Analog-to-Digital Converter (ADC) 264 as an input and also receives the second digital data signal from the first Analog-to-Digital Converter (ADC) 266 as an input. The transform component 268 can be configured to perform a mathematical transform on the complex signal so as to convert from the time domain to the frequency domain. The mathematical transform can be a complex transform such as a complex Fast Fourier Transform (FFT). A complex transform such as a complex Fast Fourier Transform (FFT) provides an unambiguous solution for the shift in frequency of a comparative signal relative to the system output signal.

The electronics include a LIDAR data generator 270 that receives the output from the transform component 268 and processes the output from the transform component 268 so as to generate the LIDAR data (distance and/or radial velocity between the reflecting object and the LIDAR chip or LIDAR system). The LIDAR data generator performs a peak find on the output of the transform component 268 to identify one or more peaks in the beat frequency.

The electronics use the one or more frequency peaks for further processing to generate the LIDAR data (distance and/or radial velocity between the reflecting object and the LIDAR chip or LIDAR system). The transform component 268 can execute the attributed functions using firmware, hardware or software or a combination thereof.

FIG. 3C shows an example of a chirp pattern for the system output signal. For instance, FIG. 3C shows the relationship between the frequency of the system output signal, time, cycles and data periods. The base frequency of the system output signal (f₀) can be the frequency of the system output signal at the start of a cycle.

FIG. 3C shows frequency versus time for a sequence of two cycles labeled cycleⱼ and cycleⱼ₊₁. In some instances, the frequency versus time pattern is repeated in each cycle as shown in FIG. 3C. The illustrated cycles do not include re-location periods and/or re-location periods are not located between cycles. As a result, FIG. 3C illustrates the results for a continuous scan where the steering of the system output signal is continuous.

Each cycle includes K data periods that are each associated with a period index k and are labeled DPₖ. In the example of FIG. 3C, each cycle includes three data periods labeled DPₖ with k=1, 2, and 3. In some instances, the frequency versus time pattern is the same for the data periods that correspond to each other in different cycles as is shown in FIG. 3C. Corresponding data periods are data periods with the same period index. As a result, each data period DP₁ can be considered corresponding data periods and the associated frequency versus time patterns are the same in FIG. 3C. At the end of a cycle, the electronics return the frequency to the same frequency level at which it started the previous cycle.

During the data period DP₁, and the data period DP₂, the electronics operate the light source such that the frequency of the system output signal changes at a linear rate a. The direction of the frequency change during the data period DP₁ is the opposite of the direction of the frequency change during the data period DP₂.

FIG. 3C labels sample regions that are each associated with a sample region index k and are labeled Rnₖ. FIG. 3C labels sample regions Rnₖ and Rnₖ₊₁. Each sample region is illuminated with the system output signal during the data periods that FIG. 3C shows as associated with the sample region. For instance, sample region Rnₖ is illuminated with the system output signal during the data periods labeled DP₁ through DP₃. The sample region indices k can be assigned relative to time. For instance, the sample regions can be illuminated by the system output signal in the sequence indicated by the index k. As a result, the sample region Rn₁₀ can be illuminated after sample region Rn₉ and before Rn₁₁.

The LIDAR system is typically configured to provide reliable LIDAR data when the object is within an operational distance range from the LIDAR system. The operational distance range can extend from a minimum operational distance to a maximum operational distance. A maximum roundtrip time can be the time required for a system output signal to exit the LIDAR system, travel the maximum operational distance to the object, and to return to the LIDAR system and is labeled τ_{M} in FIG. 3C.

Since there is a delay between the system output signal being transmitted and returning to the LIDAR system, the composite signals do not include a contribution from the LIDAR signal until after the system return signal has returned to the LIDAR system. Since the composite signal needs the contribution from the system return signal for there to be a LIDAR beat frequency, the electronics measure the LIDAR beat frequency that results from system return signal that return to the LIDAR system during a data window in the data period. The data window is labeled “W” in FIG. 3C. The contribution from the LIDAR signal to the composite signals will be present at times larger than the maximum operational time delay (τ_{M}). As a result, the data window is shown extending from the maximum operational time delay (τ_{M}) to the end of the data period.

A frequency peak in the output from the Complex Fourier transform represents the beat frequency of the composite signals that each includes a comparative signal beating against a reference signal. The beat frequencies from two or more different data periods can be combined to generate the LIDAR data. For instance, the beat frequency determined from DP₁ in FIG. 3C can be combined with the beat frequency determined from DP₂ in FIG. 3C to determine the LIDAR data. As an example, the following equation applies during a data period where electronics increase the frequency of the outgoing LIDAR signal during the data period such as occurs in data period DP₁ of FIG. 3C: f_{ub}=−f_{d}+ατ where f_{ub} is the frequency provided by the transform component, fa represents the Doppler shift (f_{d}=2νf_{c}/c) where f_{c} represents the optical frequency (fₒ), c represents the speed of light, ν is the radial velocity between the reflecting object and the LIDAR system where the direction from the reflecting object toward the chip is assumed to be the positive direction, τ is the time in which the light from the system output signal travels to the object and returns to the LIDAR system (the roundtrip time), and c is the speed of light. The following equation applies during a data period where electronics decrease the frequency of the outgoing LIDAR signal such as occurs in data period DP₂ of FIG. 3C: f_{ab}=−f_{d}−ατ where f_{db} is a frequency provided by the transform component (f_{i, LDP} determined from DP₂ in this case). In these two equations, f_{d} and τ are unknowns. The electronics solve these two equations for the two unknowns. The radial velocity for the sample region then be calculated from the Doppler shift (ν=c*f_{d}/(2f_{c})) and/or the separation distance for that sample region can be calculated from c*−τ/2. As a result, the electronics use each of the beat frequencies can as a variable in one or more equations that yield the LIDAR data. Since the LIDAR data can be generated for each corresponding frequency pair output by the transform, separate LIDAR data can be generated for each of the objects in a sample region. Accordingly, the electronics can determine more than one radial velocity and/or more than one radial separation distance from a single sampling of a single sample region in the field of view.

The data period labeled DP₃ in FIG. 3C is optional. As noted above, there are situations where more than one object is present in a sample region. For instance, during the feedback period in DP₁ for cycle₂ and also during the feedback period in DP₂ for cycle₂, more than one frequency pair can be matched. In these circumstances, it may not be clear which frequency peaks from DP₂ correspond to which frequency peaks from DP₁. As a result, it may be unclear which frequencies need to be used together to generate the LIDAR data for an object in the sample region. As a result, there can be a need to identify corresponding frequencies. The identification of corresponding frequencies can be performed such that the corresponding frequencies are frequencies from the same reflecting object within a sample region. The data period labeled DP₃ can be used to find the corresponding frequencies. LIDAR data can be generated for each pair of corresponding frequencies and is considered and/or processed as the LIDAR data for the different reflecting objects in the sample region.

An example of the identification of corresponding frequencies uses a LIDAR system where the cycles include three data periods (DP₁, DP₂, and DP₃) as shown in FIG. 3C. When there are two objects in a sample region illuminated by the LIDAR outputs signal, the transform component outputs two different frequencies for f_{ub}: fᵤ₁ and fᵤ₂ during DP₁ and another two different frequencies for f_{db}: f_{d1} and f_{d2} during DP₂. In this instance, the possible frequency pairings are: (f_{d1}, fᵤ₁); (f_{d1}, fᵤ₂); (f_{d2}, fᵤ₁); and (f_{d2}, f_{du2}). A value of f_{d} and τ can be calculated for each of the possible frequency pairings. Each pair of values for f_{d} and τ can be substituted into f₃=f_{d}−+α₃τ₀ to generate a theoretical f₃ for each of the possible frequency pairings. The value of a3 is different from the value of a used in DP₁ and DP₂. In FIG. 3C, the value of a3 is zero. In this case, the transform component also outputs two values for f₃ that are each associated with one of the objects in the sample region. The frequency pair with a theoretical f₃ value closest to each of the actual f₃ values is considered a corresponding pair. LIDAR data can be generated for each of the corresponding pairs as described above and is considered and/or processed as the LIDAR data for a different one of the reflecting objects in the sample region. Each set of corresponding frequencies can be used in the above equations to generate LIDAR data. The generated LIDAR data will be for one of the objects in the sample region. As a result, multiple different LIDAR data values can be generated for a sample region where each of the different LIDAR data values corresponds to a different one of the objects in the sample region

The processing component in FIG. 1A receives a series of comparative signals that carry different channels and are accordingly from different sample regions. As a result, the processing components in FIG. 1A provide LIDAR data for series of sample regions that were illuminated by system output signals carrying different channels. The series of sample regions for which the processing component provides LIDAR data can be the same as the series of sample regions that were illuminated. The processing component configuration of FIG. 3A through FIG. 3C can also be used for the processing components of FIG. 1B. However, the processing components 28 of FIG. 1B receive comparative signals that carry only one of the channels. As a result, when the processing components 28 in FIG. 1B are constructed according to FIG. 3A through FIG. 3C, each of the processing components provides LIDAR data for a series of sample regions that were illuminated by the system output signal carrying only one of the channels.

In the LIDAR system of FIG. 1C, the electronics from different processing components 28 can be combined so that beating signals are combined electronically rather than optically. For instance, each of the processing components 28 in a LIDAR system according to FIG. 1C can include the optical-to-electrical assembly of FIG. 3A. FIG. 3D is a schematic of the relationship between the first light sensor 223, the second light sensor 224, the first auxiliary light sensor 218, and the second auxiliary light sensor 220 in each of the optical-to-electrical assemblies from FIG. 3A and the electronics. Since each of the different processing components 28 receives a LIDAR input signal carrying a different channel, FIG. 3D illustrates the first light sensor 223, the second light sensor 224, the first auxiliary light sensor 218, and the second auxiliary light sensor 220 associated with the channel received by the light sensor.

In FIG. 3D, the electronics from different processing components 28 (FIG. 1C) are combined so as to form the common processing component 72. The first data line 228 from each of the different first balanced detectors 225 carries the first data signal to a first electrical multiplexer 272. The first electrical multiplexer 272 outputs the first data signals from different first data lines 228 on a common data line 273. Since system output signals that are from the same core and that carry different channels are serially output from the LIDAR system, the processing component 28 (FIG. 1C) configured to receive the first comparative signal carrying channel i receives the first comparative signal in response to the signal directing component 14 on the core being operated such that the system output signal carrying channel i is output from the LIDAR system. Additionally, processing component(s) 28 that are not configured to receive the comparative signal carrying channel i do not substantially receive a first comparative signal in response to the signal directing component 14 being operated such that the system output signal carrying channel i is output from the LIDAR system. Since the system output signals that carry different channels from the same core are serially output from the LIDAR system, the comparative signals carrying different channels are serially received at different processing component(s) 28 although there may be some overlap of different channels that occurs. Since different processing component(s) 28 serially receive the comparative signals carrying different channels, the first common data line 273 carries first data signals that carry different channels in series. Accordingly, the first common data line 273 carries electrical data signals that are each an electrical representation of the first composite signals and that each carries a different one of the channels in series. There may be some short term overlap between channels in the series of first data signals, however, the overlap does not occur in the data windows illustrated in FIG. 3C. The first common data line 273 carries the series of first data signals to the first Analog-to-Digital Converter (ADC) 264.

The second data lines 232 from each of the different second balanced detectors 226 carries the second data signal to a second electrical multiplexer 274. The second electrical multiplexer 274 outputs the second data signals from different second data line 232 on a second common data line 275. The first common data line and the second common data line are each an example of a common data line. As noted above, the processing component(s) 28 serially receive the first comparative signals carrying different channels. As a result, the second common data line 275 carries second data signals that carry different channels in series. Accordingly, the second common data line 275 carries electrical data signals that are each an electrical representation of the second composite signals and that each carries a different one of the channels in series. There may be some short term overlap between channels in the series of second data signals, however, the overlap does not occur during the data windows illustrated in FIG. 3C. The second common data line 275 carries the series of second data signals to the second Analog-to-Digital Converter (ADC) 266.

The transform mechanism 238 and LIDAR data generator 270 of FIG. 3D can be operated as disclosed in the context of FIG. 3A through FIG. 3C. For instance, the first Analog-to-Digital Converter (ADC) 264 converts the first data signal from an analog form to a digital form and outputs the first digital data signal. The second Analog-to-Digital Converter (ADC) 266 converts the second data signal from an analog form to a digital form and outputs a second digital data signal.

A first digital data signal and the second digital data signal carrying the same channel act together as a complex signal where the first digital data signal acts as the real component of the complex signal and the second digital data signal acts as the imaginary component of the complex data signal. The electronics are configured such that the first digital data signals and the second digital data signals carrying the same channel are concurrently received by the LIDAR data generator 270. As a result, the LIDAR data generator 270 receives a complex signal that carries different channels in series. The LIDAR data generator 270 can generate LIDAR data for each of the different channels. As a result, the data generator 270 can generate LIDAR data for each sample region that is illuminated by the system output signals carrying the series of channels.

In another embodiment of a LIDAR system where the relationship between sensors in the optical-to-electrical assembly from FIG. 3A and electronics in the LIDAR system is constructed according to FIG. 3D, the electronics operate the electrical multiplexers as a switch that can be operated by the electronics. As a result, the electronics can operate the first electrical multiplexer 272 so as select which of the first data signals are output on the common data line 273 and can operate the second electrical multiplexer 274 so as select which of the second data signals are output on the second common data line 275. As a result, the LIDAR system can be configured to concurrently output the system output signals that carry different channels. For instance, the LIDAR chip can be configured to concurrently output each of the LIDAR output signals carrying the different channels. As, the signal directing component 14 can be configured to direct the outgoing LIDAR system to one or more than one of the alternate waveguides 16. In an example where the signal directing component 14 is configured to direct the outgoing LIDAR system all N of the alternate waveguides 16, the signal directing component can be a signal splitter.

When the LIDAR system concurrently outputs system output signals that carry different channels, each of the different processing components 28 can concurrently receive a first LIDAR input signal carrying one of the channels. Accordingly, the first data lines 228 from each of the different processing components 28 concurrently carries the first data signal to the first electrical multiplexer 272. As a result, the first electrical multiplexer 272 concurrently receives multiple first data signals that each carries a different channel and is from a different processing component 28. The electronics use the switching functionality of the first electrical multiplexer 272 to operate the first electrical multiplexer 272 such that the first electrical multiplexer 272 outputs the first data signals carrying different channels in series. As a result, the first common data line 273 carries first data signals that carry different channels in series. An example of a suitable channel series, includes, but is not limited to, the sequence of channels having channel index i=1 through N from i=1 in the numerical sequence from i=1 through to i=N.

The second data lines 232 from each of the different processing components 28 concurrently carries a second data signal to the second electrical multiplexer 274. As a result, the second electrical multiplexer 274 concurrently receives multiple second data signals that each carries a different channel and is from a different processing component 28. The electronics use the switching functionality of the second electrical multiplexer 274 to operate the second electrical multiplexer 274 such that the second electrical multiplexer 274 outputs the second data signals carrying different channels in series. As a result, the second data line 275 carries second data signals that carry different channels in series.

The transform mechanism 238 and LIDAR data generator 270 of FIG. 3D can be operated as disclosed in the context of FIG. 3A through FIG. 3C. For instance, the first Analog-to-Digital Converter (ADC) 264 converts the first data signal from an analog form to a digital form and outputs the first digital data signal. The second Analog-to-Digital Converter (ADC) 266 converts the second data signal from an analog form to a digital form and outputs a second digital data signal.

The first electrical multiplexer 272 and the second electrical multiplexer 274 are operated such that the first data line 273 and the second data line 275 concurrently carry the same channel. As a result, the first digital data signal and the second digital data signal output from the first Analog-to-Digital Converter (ADC) 264 and the second Analog-to-Digital Converter (ADC) 266 concurrently carry the same channel. The first digital data signal and the second digital data signal carrying the same channel act together as a complex signal where the first digital data signal acts as the real component of the complex signal and the second digital data signal acts as the imaginary component of the complex data signal. The first digital data signals and the second digital data signals carrying the same channel are concurrently received by the LIDAR data generator 270. As a result, the LIDAR data generator 270 receives a complex signal that carries different channels in series. The LIDAR data generator 270 can generate LIDAR data for each of the channel in the series of channels. As a result, the data generator 270 can generate LIDAR data for each sample region that is illuminated by the system output signals carrying the series of channels.

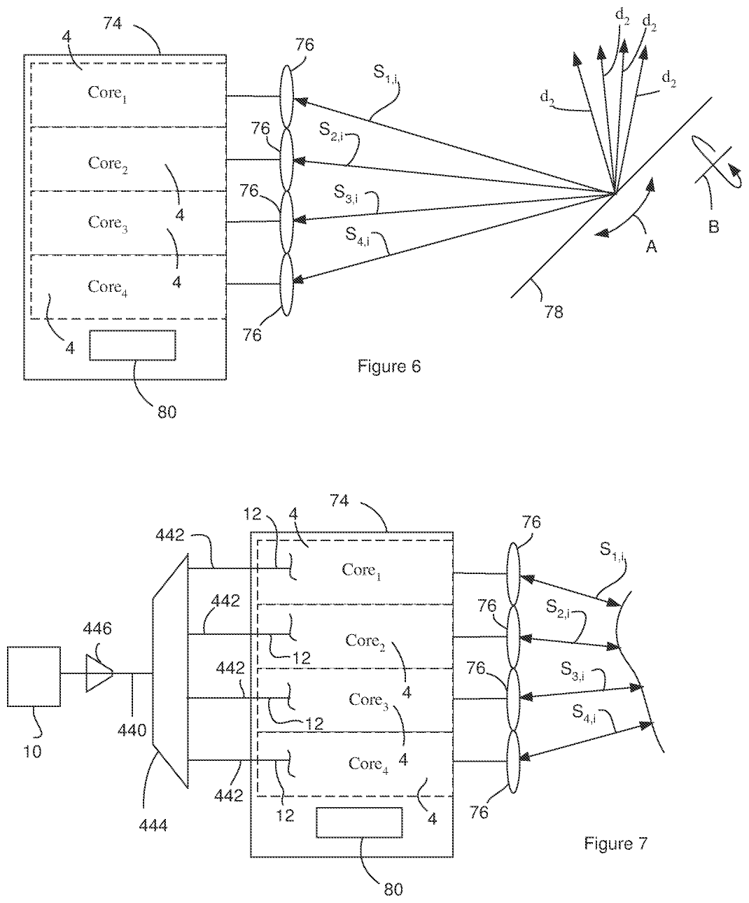

An alternative to the first electrical multiplexer 272 and/or the second electrical multiplexer 274 is to provide an electrical node where the first data lines 228 from each of the different first balanced detectors 225 are in electrical communication with one another and a second electrical node the second data lines 232 from each of the different second balanced detectors 226 are in electrical communication with one another. As a result, the outputs of the light sensors such as the first balanced detectors 225 are effectively electrically connected to one another and the outputs of light sensors such as the second balanced detectors 226 are effectively electrically connected to one another. As an example, FIG. 3E illustrates the arrangement of FIG. 3D modified such that the first data lines 228 from each of the different first balanced detectors 225 are in electrical communication with the first common data line 273. Since the LIDAR system outputs system output signals that carry different channels in series, the first common data line 273 carries first data signals that carry different channels in series. While there may be some overlap between channels that are adjacent to one another in the series, the overlap does not occur during the data window. Additionally, the second data lines 232 from each of the different second balanced detectors 226 are in electrical communication with the second common data line 275. Since the LIDAR system outputs system output signals that carry different channels in series, the second common data line 275 carries second data signals that carry different channels in series. While there may be some overlap between channels that are adjacent to one another in the series, the overlap does not occur during the data window. Since the first common data line 273 carries first data signals that carry different channels in series and the second common data line 275 carries second data signals that carry different channels in series as also occurs in the LIDAR system of FIG. 6D, the transform mechanism 238 and LIDAR data generator 270 can be operated as disclosed in the context of FIG. 3E to generate LIDAR data for each sample region that is illuminated by the system output signals carrying the series of channels.

In a LIDAR system constructed according to FIG. 3E, during a cycle when the LIDAR system is outputting a system output signal that carries channel i, the optical-to-electrical assembly included in the processing component configured to receive the current channel i (the active processing component) receives the first LIDAR input signals that carries channel i during at least the data window while the processing component that are not configured to receive the current channel i (the inactive processing component(s)) do not receive a first LIDAR input signal. However, the inactive processing component(s) continue to receive a reference signal during at least the data window. Light from the reference signal(s) received by the inactive processing component(s) can pass through the optical-to-electrical assemblies and become noise in electrical signals such as the first data signals and the second data signals.

In some instances, it may be desirable to fully or partially attenuate all or a portion of the reference signal(s) received by the inactive processing component(s). For instance, the reference waveguides 32 (FIG. 1C) can each optionally include an optical attenuator 276. The attenuators 276 can be operated by the electronics so as to fully or partially attenuate the reference signal guided by the reference waveguide 32 along which the attenuator 276 is positioned.

The processing component labeled 28 in FIG. 1C that serves as the active processing component and the processing component(s) labeled 28 in FIG. 1C that serve as the inactive processing component(s) changes as the channel carried by the system output signal changes. As a result, the electronics can change the reference signal(s) that are attenuated in response to changes in the channel that is currently being carried in the system output signal. For instance, the electronics can operate the attenuators 276 such that the reference signal to be received by an active processing component is not attenuated or is not substantially attenuated. Additionally, the electronics can operate the attenuators 276 such that the reference signal(s) to be received by all or a portion of the inactive processing component(s) is fully or partially attenuated. Since the reference signal(s) to be received by all or a portion of the inactive processing component(s) is fully or partially attenuated, the amount of light from the reference signals that is actually received by the inactive processing component(s) is reduced. As a result, the attenuated light is not a source of noise in the first data signal and the second data signal.

Although the optical attenuators 276 are shown positioned on the reference waveguides 32 of FIG. 1C, the optical attenuators 276 can be positioned on all or a portion of the reference waveguides 32 illustrated in the imaging systems of FIG. 1A and FIG. 1B. The electronics can operate the variable optical attenuators 276 so as to achieve the desired level of attenuation of the power of the reference signal.

Suitable devices suitable for use as an optical attenuator 276 include, but are not limited to, variable optical attenuators (VOAs), PIN diodes, and Mach-Zehnder modulators. An example of a suitable optical attenuator can be found in U.S. patent application Ser. No. 17/396,616, filed on Aug. 6, 2021, entitled “Carrier Injector Having Increased Compatibility,” and incorporated herein in its entirety.

Suitable platforms for the LIDAR chip include, but are not limited to, silica, indium phosphide, and silicon-on-insulator wafers. FIG. 4 is a cross section of a silicon-on-insulator wafer. A silicon-on-insulator (SOI) wafer includes a buried layer 300 between a substrate 302 and a light-transmitting medium 304. In a silicon-on-insulator wafer, the buried layer 300 is silica while the substrate 302 and the light-transmitting medium 304 are silicon. The substrate of an optical platform such as an SOI wafer can serve as the base for a LIDAR chip. For instance, in some instances, the optical components shown in FIG. 1A through FIG. 1C can be positioned on or over the top and/or lateral sides of the same substrate. As a result, the substrate of an optical platform such as an SOI wafer can serve as base 298 shown in FIG. 2B.

The portion of the LIDAR chip illustrated in FIG. 4 includes a waveguide construction that is suitable for use with chips constructed from silicon-on-insulator wafers. A ridge 306 of the light-transmitting medium 304 extends away from slab regions 308 of the light-transmitting medium 304. The light signals are constrained between the top of the ridge and the buried layer 300. As a result, the ridge 306 at least partially defines the waveguide.

The dimensions of the ridge waveguide are labeled in FIG. 4. For instance, the ridge has a width labeled w and a height labeled h. A thickness of the slab regions is labeled t. For LIDAR applications, these dimensions can be more important than other applications because of the need to use higher levels of optical power than are used in other applications. The ridge width (labeled w) is greater than 1 μm and less than 4 μm, the ridge height (labeled h) is greater than 1 μm and less than 4 μm, the slab region thickness is greater than 0.5 μm and less than 3 μm. These dimensions can apply to straight or substantially straight portions of the waveguide, curved portions of the waveguide and tapered portions of the waveguide(s). Accordingly, these portions of the waveguide will be single mode. However, in some instances, these dimensions apply to straight or substantially straight portions of a waveguide. Additionally or alternately, curved portions of a waveguide can have a reduced slab thickness in order to reduce optical loss in the curved portions of the waveguide. For instance, a curved portion of a waveguide can have a ridge that extends away from a slab region with a thickness greater than or equal to 0.0 μm and less than 0.5 μm. While the above dimensions will generally provide the straight or substantially straight portions of a waveguide with a single-mode construction, they can result in the tapered section(s) and/or curved section(s) that are multimode. Coupling between the multi-mode geometry to the single mode geometry can be done using tapers that do not substantially excite the higher order modes. Accordingly, the waveguides can be constructed such that the signals carried in the waveguides are carried in a single mode even when carried in waveguide sections having multi-mode dimensions. The waveguide construction of FIG. 4 is suitable for all or a portion of the waveguides on a LIDAR chip constructed according to FIG. 1A through FIG. 1C.

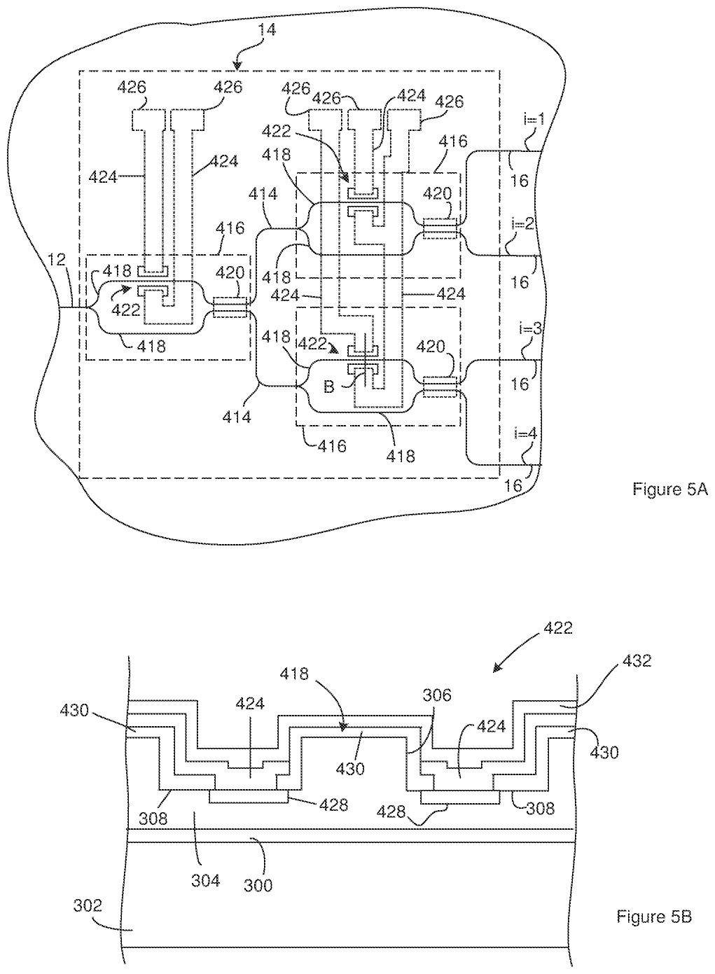

Suitable signal directing components 14 for use with the LIDAR chip include, but are not limited to, optical switches such as cascaded Mach-Zehnder interferometers and micro-ring resonator switches. In one example, the signal directing component 14 includes cascaded Mach-Zehnder interferometers that use thermal or free-carrier injection phase shifters. FIG. 5A and FIG. 5B illustrate an example of an optical switch that includes cascaded Mach-Zehnder interferometers 416. FIG. 5A is a topview of the optical switch. FIG. 5B is a cross section of the optical switch shown in FIG. 5A taken along the line labeled B in FIG. 5A.

The optical switch receives the outgoing LIDAR signal from the utility waveguide 12. The optical switch is configured to direct the outgoing LIDAR signal to one of several alternate waveguides 16. The optical switch includes interconnect waveguides 414 that connect multiple Mach-Zehnder interferometers 416 in a cascading arrangement. Each of the Mach-Zehnder interferometers 416 directs the outgoing LIDAR signal to one of two interconnect waveguides 414. The electronics can operate each Mach-Zehnder so as to select which of the two interconnect waveguides 414 receives the outgoing LIDAR signal from the Mach-Zehnder interferometer 416. The interconnect waveguides 414 that receive the outgoing LIDAR signal can be selected such that the outgoing LIDAR signal is guided through the optical switch to a particular one of the alternate waveguides 16.

Each of the Mach-Zehnder interferometers 416 includes two branch waveguides 418 that each receives a portion of the outgoing LIDAR signal from the utility waveguide 12 or from an interconnect waveguide 414. Each of the Mach-Zehnder interferometers 416 includes a direction component 420 that receives two portions of the outgoing LIDAR signal from the branch waveguides 418. The direction component 420 steers the outgoing LIDAR signal to one of the two interconnect waveguides 414 configured to receive the outgoing LIDAR signal from the direction component 420. The interconnect waveguide 414 to which the outgoing LIDAR signal is directed is a function of the phase differential between the two different portions of the outgoing LIDAR signal received by the direction component 420. Although FIG. 5A illustrates a directional coupler operating as the direction component 420, other direction components 420 can be used. Suitable alternate direction components 420 include, but are not limited to, Multi-Mode Interference (MIMI) devices and tapered couplers.

Each of the Mach-Zehnder interferometers 416 includes a phase shifter 422 positioned along one of the branch waveguides 418. The output component includes conductors 424 in electrical communication with the phase shifters 422. The conductors 424 are illustrated as dashed lines so they can be easily distinguished from underlying features. The conductors 424 each terminate at a contact pad 426. The contact pads 426 can be used to provide electrical communication between the conductors 424 and the electronics. Accordingly, the conductors 424 provide electrical communication between the electronics and the phase shifters 422 and allow the electronics to operate the phase shifters 422. Suitable conductors 424 include, but are not limited to, metal traces. Suitable materials for the conductors include, but are not limited to, titanium, aluminum and gold.

The electronics can operate each of the phase shifters 422 so as to control the phase differential between the portions of the outgoing LIDAR signal received by a direction component 420. In one example, a phase shifter 422 can be operated so as to change the index of refraction of a portion of at least a portion of a branch waveguide 418. Changing the index of a portion of a branch waveguide 418 in a Mach-Zehnder interferometer 416, changes the effective length of that branch waveguides 418 and accordingly changes the phase differential between the portions of the outgoing LIDAR signal received by a direction component 420. The ability of the electronics to change the phase differential allows the electronics to select the interconnect waveguide 414 that receives the outgoing LIDAR signal from the direction component 420.

FIG. 5B illustrates one example of a suitable construction of a phase shifter 422 on a branch waveguide 418. The branch waveguide 418 is at least partially defined by a ridge 306 of the light-transmitting medium 304 that extends away from slab regions 308 of the light-transmitting medium 304. Doped regions 428 extend into the slab regions 308 with one of the doped regions including an n-type dopant and one of the doped regions 428 including a p-type dopant. A first cladding 430 is positioned between the light-transmitting medium 304 and a conductor 424. The conductors 424 each extend through an opening in the first cladding 430 into contact with one of the doped regions 428. A second cladding 432 is optionally positioned over the first cladding 430 and over the conductor 424. The electronics can apply a forward bias can be applied to the conductors 424 so as to generate an electrical current through the branch waveguide 418. The resulting injection of carriers into the branch waveguide 418 causes free carrier absorption that changes the index of refraction in the branch waveguide 418.

The first cladding 430 and/or the second cladding 432 illustrated in FIG. 5B can each represent one or more layers of materials. The materials for the first cladding 430 and/or the second cladding 432 can be selected to provide electrical isolation of the conductors 424, lower index of refraction relative to the light-transmitting medium 304, stress reduction and mechanical and environmental protection. Suitable materials for the first cladding 430 and/or the second cladding 432 include, but are not limited to, silicon nitride, tetraorthosilicate (TEOS), silicon dioxide, silicon nitride, and aluminum oxide. The one or more materials for the first cladding 430 and/or the second cladding 432 can be doped or undoped.

In instances where the LIDAR system includes multiple cores, the LIDAR system can include multiple signal directors 76 and different signal directors 76 can receive LIDAR output signals from different selections of the signal directors 76. As an example, FIG. 6 illustrates the LIDAR system of FIG. 2 modified to have multiple signal directors 76 that each receives LIDAR output signals from a different one of the cores.

FIG. 1A through FIG. 1C illustrate each of the cores including a different light source 10. However, the multiple cores, all of the cores, or a portion of the cores can receive the outgoing LIDAR signal from a common light source. In some instances, the cores are arranged in groups where each core in a group receives the outgoing LIDAR signal from the same common light source and the cores in different groups receives the outgoing LIDAR signal from the different common light sources. In some instances, a group of cores can include a single one of the cores. As an example, FIG. 7 illustrates the LIDAR system of FIG. 2 where a light source 10 is located external to the cores and each of the cores receives an outgoing LIDAR signal from the light source.

A first optical link 440 provide optical communication between the light source and a signal splitter 442. Second optical links 444 provide optical communication between the signal splitter 442 and the utility waveguides 12 on different cores 4. The light source 10 outputs a preliminary signal that is received on the first optical link 440. The signal splitter 442 receives the preliminary signal from the first optical link 440. The signal splitter 442 splits the preliminary signal into a split signals that are each received on a different one of the second optical links 444. Each of the utility waveguides 12 receive a split signal from a different one of the optical links 444. The portion of a split signal that enters a utility waveguide serves as the outgoing LIDAR signal.

The LIDAR system can optionally include an amplifier 446 positioned along the first optical link 440 so as to amplify the power of the preliminary signal. Suitable amplifiers 446 for use along an optical link, include, but are not limited to, SOAs, Erbium Doped Fiber Amplifiers (EDFAs), and Preasodymium Doped Fiber Amplifiers (PDFAs).

When it is desirable for the different outgoing LIDAR signals to have the same or substantially the same distribution of wavelengths, suitable signal splitters 442 include, but are not limited to, wavelength independent signal combiners such as an optical couplers, y-junctions, MMIs, cascaded evanescent optical couplers, and cascaded y-junctions. When it is desirable for the different outgoing LIDAR signals to have different wavelength distributions, suitable signal splitters 442 include, but are not limited to, wavelength dependent signal splitters 442 including optical demultiplexers such as Arrayed Waveguide Gratings (AWGs), and echelle gratings.

In some instances where multiple different cores receive an outgoing LIDAR signal from a common light source, only one of the cores that receives its outgoing LIDAR signal from the common light source includes a control branch. As a result, the other cores that receives an outgoing LIDAR signal from the same common light source can exclude the directional coupler 66, control waveguide 68, and control components 70 illustrated in FIG. 1A through FIG. 1C.

As is evident from FIG. 1A and FIG. 1B, the LIDAR system can optionally include one or more light signal amplifiers 446. For instance, an amplifier 446 can optionally be positioned along a utility waveguide as illustrated in the LIDAR system of FIG. 1A. In another example, an amplifier 446 is optionally positioned along all or a portion of the alternate waveguides 16 as illustrated in the LIDAR system of FIG. 1B. The electronics can operate the amplifier 446 so as to amplify the power of the outgoing LIDAR signal and accordingly of the system output signal. The electronics can operate each of the amplifiers 446 so as to amplify the power of the outgoing LIDAR signal. Suitable amplifiers 446 for use on the LIDAR chip, include, but are not limited to, Semiconductor Optical Amplifiers (SOAs).

The amplifiers 446 shown in FIG. 1A and FIG. 1B are each positioned before one of the splitters 24. In some instances, this location of the amplifiers 446 can cause saturation of one or more components selected from a group consisting of the first auxiliary light sensor 218, the second auxiliary light sensor 220, the first light sensor 223, and the second light sensor 224. For instance, the amplifier 446 can increase power level of the reference signal to a level where saturation occurs. A beam dump can be used to reduce the power level of the reference signal to a level where saturation is reduced or eliminated.

As is evident from FIG. 3B and FIG. 3D, the LIDAR system can optionally include one or more electrical signal amplifiers 447. Each of the amplifiers 447 is positioned so as to provide amplification of a first data signal traveling between a first light sensor such as a first balanced detector 225 and an analog to digital converter or a second data signal traveling between a second light sensor such as a second balanced detector 226 and an analog to digital converter. Suitable electrical signal amplifiers 447 include, but are not limited to, Transimpedance Amplifiers (TIAs).

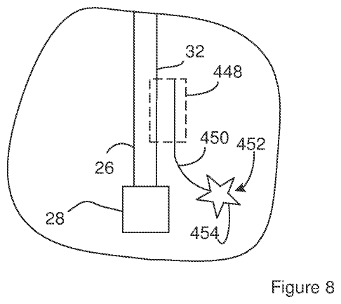

FIG. 8 illustrates a portion of a LIDAR chip that includes a reference waveguide 32 used in conjunction with a beam dump configured to reduce the power level of the reference signal carried on the reference waveguide 32. The reference waveguide 32 carries the reference signal to a splitter 448 that moves a portion of the reference signal from the reference waveguide 32 onto a dump waveguide 450 as a dump signal. The dump waveguide 450 carries the dump signal to a beam dump 452.

The beam dump 452 is configured to scatter the dump signal without reflecting a substantial amount of the light from the dump signal back into the dump waveguide 450. For instance, the beam dump 452 can be a recess 454 etched into the light-transmitting medium of a silicon-on-insulator wafer to a depth where the dump signal is incident on one or more lateral sides of the recess 454. The recess 454 can be shaped so as to cause scattering of the dump signal. For instance, the recess 454 can have the shape of a star or can include any number of irregularly positioned lateral sides. In some instances, the recess 454 can extends through the light transmitting to medium to an underlying layer such as the buried layer of a silicon-on-insulator wafer.

The splitter 448 can be constructed so as to control the percentage of the reference signal power transferred to the dump waveguide. Increasing the percentage of the reference signal power transferred to the dump waveguide increases attenuation of the power of reference signal and accordingly decreases the power of the signals received by all or a portion of the light sensors selected from a group consisting of the first auxiliary light sensor, the second auxiliary light sensor, the first light sensor, and the second light sensor. The drop in power of the light signals received by all or a portion of the light sensors reduces the opportunity for saturation. Suitable splitters 448 include, but are not limited to, 1×2 splitters including optical couplers, y-junctions, and MMIs. In some instances, the splitters 448 is configured such that percentage of the reference signal power transferred to the dump waveguide 450 is greater than or equal to 0.5%, or 1% and less than or equal to 2%, 10%, or 20%.

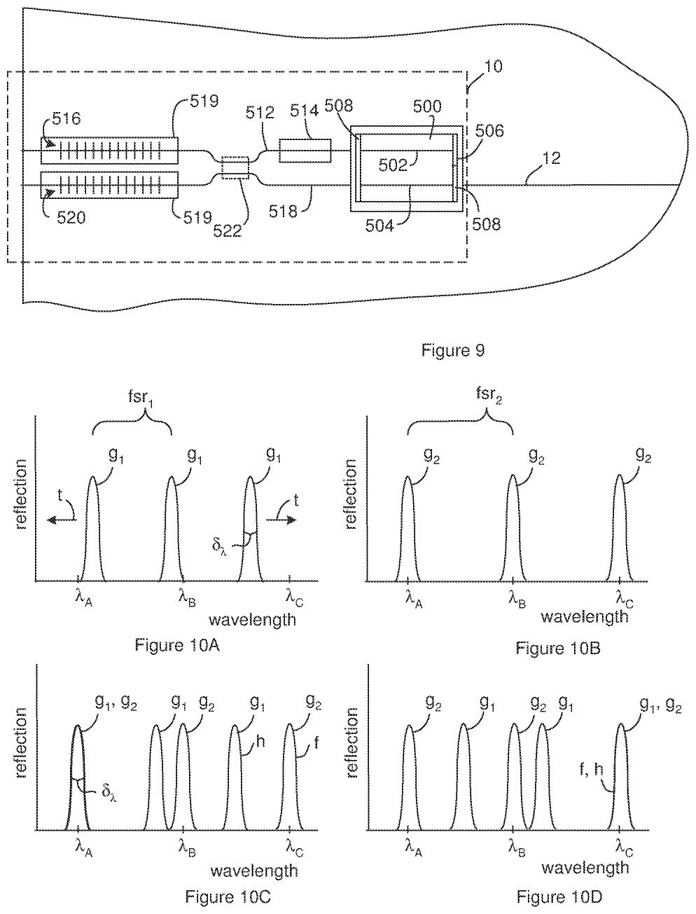

FIG. 9 is a schematic of a topview of a portion of a LIDAR chip that includes a light source 10 this suitable for use in the imaging systems. The light source 10 includes a gain medium 500 for a laser. The gain medium 500 includes a laser waveguide 502 and an amplifier waveguide 504.

A highly, fully, or partially reflective layer 506 can be positioned on the gain medium over a facet of the laser waveguide 502. In some instances, an anti-reflective coating 508 is positioned on the opposing side of the gain medium 500 over the facet of the amplifier waveguide 504 and also over the facet of the laser waveguide 502. An anti-reflective coating 508 can also be positioned on an opposing facet of the amplifier waveguide 504. A suitable anti-reflective coating 508 includes, but is not limited to, single-layer coatings such as silicon nitride or aluminum oxide, or multi-layer coatings, which may contain silicon nitride, aluminum oxide, and/or silica. A suitable reflective layer 506 includes, but is not limited to, a layer of metal on the gain medium, one or more dielectric layers configured as a high-reflectivity (HR) coating.

An optical coupler 522 is positioned along a cavity waveguide 512 and an auxiliary waveguide 518. Suitable optical couplers 520 include, but are not limited to, 2×2 optical couplers and multimode interferometers. A phase shifter 514 is positioned along the cavity waveguide 512.

During operation of the light source, an electrical current is driven through the gain medium 500 so as to cause the gain medium 500 to output an output light signal on the laser waveguide 502. The output light signal passes through the anti-reflective coating 508. The laser waveguide 502 is aligned with the cavity waveguide 512 such that the cavity waveguide 512 receives the output light signal. The cavity waveguide 512 carries the output light signal to the optical coupler 520. The optical coupler 520 passes a first portion of the output light signal on the cavity waveguide 512 and moves a second portion of the output light signal onto the auxiliary waveguide 518. The portion of the output light signal moved onto the auxiliary waveguide 518 serves as a transferred signal and the portion of the output light signal passed to the cavity waveguide 512 serves as an outgoing passed signal.

The cavity waveguide 512 carries the outgoing passed signal to the first optical grating 516. The first optical grating 516 returns at least part of the outgoing passed signal to the cavity waveguide 512 as a first returned signal. The cavity waveguide 512 carries the first returned signal to the optical coupler 520. The optical coupler 520 passes a first portion of the first returned signal on the cavity waveguide 512 and moves a second portion of the first returned signal onto the auxiliary waveguide 518. The portion of the first returned signal moved onto the auxiliary waveguide 518 serves as a transferred return signal. The portion of the first returned signal passed on the cavity waveguide 512 serves as a passed return signal.

The auxiliary waveguide 518 carries the transferred signal to the second optical grating 520. The second optical grating 520 returns at least part of the transferred signal to the auxiliary waveguide 518 as a second returned signal. The auxiliary waveguide 518 carries the second returned signal to the optical coupler 520. The optical coupler 520 passes a first portion of the second returned signal on the auxiliary waveguide 518 and moves a second portion of the second returned signal onto the cavity waveguide 512. The portion of the second returned signal moved onto the cavity waveguide 512 serves as a second transferred return signal. The portion of the first returned signal passed on the auxiliary waveguide 518 serves as a second passed return signal.

The cavity waveguide 512 returns the passed return signal and the second transferred return signal to the gain medium 500 such that at least a portion of the passed return signal and the at least a portion of second transferred return signal is received by the laser waveguide 502. The laser waveguide 502 carries the received portions of the passed return signal and the second transferred return signal to the reflective layer 506.

The auxiliary waveguide 518 carries the transferred return signal and the second passed return signal to the gain medium 500. The amplifier waveguide 504 is aligned with the auxiliary waveguide 518 such that at least a portion of the transferred return signal and at least a portion of the second passed return signal is received by the amplifier waveguide 504. The electrical current driven through the gain medium 500 amplifies the received portion of the transferred return signal and the second passed return signal such that the amplifier 510 outputs an amplified transferred return signal. Accordingly, the amplified transferred return signal include, consists of, or consists essentially of light from the transferred return signal and the second passed return signal. The utility waveguide 12 is aligned with the amplifier waveguide 504 such that at least a portion of the amplified transferred return signal is received by the utility waveguide 12. The portion of the amplified transferred return signal received by the utility waveguide 12 serves as the outgoing LIDAR signal.

The reflective layer 506, the first optical grating 516, and the second optical grating 520 define a laser cavity. For instance, light resonates between the reflective layer 506 and the first optical grating 516. Light also resonates between the reflective layer 506 and the second optical grating 520. The unamplified output of the laser cavity exits the laser cavity through a port of optical coupler 520. For instance, the combination of the transferred return signal and the second passed return signal serve as the unamplified output of the laser cavity.

The first optical grating 516 and/or the second optical grating 520 can be tunable. For instance, FIG. 10A is an example reflection profile for an optical grating that can serve as the first optical grating 516. The optical grating reflects different wavelengths of light at different intensities. In particular, the y-axis of FIG. 10A shows the intensity of light that the Bragg grating reflects at the wavelength shown on the x-axis. The y-axis of FIG. 10A can be units of intensity, percentages, or can be normalized.

As is evident in FIG. 10A, the reflection profile includes multiple peaks that each represents a reflection band. Each of the reflection bands for the first optical grating 516 are labeled g₁. The bandwidth of a reflection band can be a function of the full width half-maximum of the reflection band (δλ). The reflection bands have a maximum and the maxima are separated by the Free Spectral Range (FSR) of the optical grating.

In FIG. 10A, the Free Spectral Range (FSR) of the first optical grating 516 is represented by fsr₁. The first optical grating 516 is configured such that the selection of wavelengths in each of the reflection bands can be tuned. For instance, the first optical grating 516 can be associated with a tuner 519 as shown in FIG. 9. The tuner 519 can be operated by the electronics so as to tune the selection of wavelengths in each of the reflection bands. For instance, the Free Spectral Range (FSR) of the first optical grating 516 as represented by fsr₁ can represent the Free Spectral Range (FSR) of the first optical grating 516 when the tuner is not operated by the electronics. The electronics can operate the tuner so as to shift the selection of wavelengths the reflection bands of FIG. 10A as illustrated by the arrows labeled t. Accordingly, the electronics can operate the tuner associated with the first optical grating 516 so as to change the Free Spectral Range (FSR) of the first optical grating 516 and/or shift the reflection bands to higher or lower wavelengths. As a result, the electronics can operate the tuner associated with the first optical grating 516 so as to change the wavelengths in each of the reflection bands.

In some instances, the second optical grating 520 is configured such that the selection of wavelengths in each of the reflection bands can be tuned as described for the first optical grating 516. For instance, as shown in FIG. 9, the second optical grating 520 can be associated with a tuner 519 that is operated by the electronics so as to tune the selection of wavelengths in each of the reflection bands. However, the second optical grating 520 need not be associated with a tuner. For the purposes of illustration, FIG. 10B is an example reflection profile for an optical grating that can serve as a second optical grating 520 that is not associated with a tuner. The Free Spectral Range (FSR) of the second optical grating 520 is represented by fsr₂. Each of the reflection bands for the second optical grating 520 are labeled g₂. The reflection bands (g₂) have maxima at the wavelengths labeled λ_{A}, λ_{B}, and λ_{C}.

Wavelengths labeled λ_{A}, λ_{B}, and λ_{C} are shown in FIG. 10A and FIG. 10B. In FIG. 10A, the reflection bands for the first optical grating 516 are labeled g₁ and are not aligned with any of the wavelengths labeled λ_{A}, λ_{B}, and λ_{C}. FIG. 10C shows the reflection profiles for the first optical grating 516 and the second optical grating 520 on the same graph. The reflection bands (g₂) for the second optical grating 520 have maxima at the wavelengths labeled λ_{A}, λ_{B}, and λ_{C} as shown in FIG. 10B. However, the first optical grating 516 has been tuned such that one of the reflection bands (g₁) for the first optical grating 516 is positioned at the wavelength labeled λ_{A}. When a reflection band (g₁) for the first optical grating 516 and a reflection band (g₂) for the second optical grating 520 share a wavelength(s), the light source 10 lases and provides an output at the shared wavelength(s). Accordingly, the unamplified output of the laser cavity and the amplified output of the laser cavity include, consist of, or consist essentially of light of the shared wavelength(s). In the case of FIG. 10C, the unamplified output of the laser cavity and the amplified output of the laser cavity include, consist of, or consist essentially of wavelength(s) within the reflection band associated with λ_{A}.

As is evident from FIG. 10C, the free spectral range of the second optical grating 520 is different from the free spectral range of the first optical grating 516. The free spectral ranges are selected such that a reflection band (g₁) for the first optical grating 516 can share wavelength with a reflection band (g₂) for the second optical grating 520 without the remaining reflection bands (g₂) from the second optical grating 520 sharing wavelength with any reflection bands (g₁) for the first optical grating 516. For instance, FIG. 10C shows overlap between a reflection band (g₂) from the second optical grating 520 and a reflection band (g₁) for the first optical grating 516 without any overlap between the remaining reflection bands. This arrangement is a result of the difference between the free spectral range of the second optical grating 520 and the free spectral range of the first optical grating 516. In some instances, the free spectral range of the second optical grating 520 is within the free spectral range of the first optical grating 516+/−an amount that less than 10% of free spectral range of the first optical grating 516, an amount that less than 6% of free spectral range of the first optical grating 516, or an amount that less than 2% of free spectral range of the first optical grating 516.

In some instances, the first optical grating 516 and/or the second optical grating 520 are tuned such that the full width half-maximum (δλ) of a reflection band (g₂) from the second optical grating 520 shares more than 10%, 20%, or 50% of the wavelengths with the full width half-maximum (δλ) of a reflection band (g₁) from the first optical grating 516. In Figure the first optical grating 516 is tuned such that the full width half-maximum (δλ) of a reflection band (g₂) from the second optical grating 520 shares 100% of the wavelengths with the full width half-maximum (δλ) of a reflection band (g₁) from the first optical grating 516.

The first optical grating 516 and/or the second optical grating 520 can be tuned such that multiple different selections of reflection bands can overlap. For instance, FIG. 10D illustrates the results of tuning the first optical grating 516 and/or the second optical grating 520 of FIG. 10C such that the reflection band labeled h in FIG. 10C overlaps the reflection band labeled fin FIG. 10C. As a result, FIG. 10D illustrates different reflection bands overlapping than are overlapped in FIG. 10C.

In some instances, the first optical grating 516 and the second optical grating 520 in FIG. 9 are switched. Accordingly, the first optical grating 516 can be positioned along the auxiliary waveguide 518 and the second optical grating 520 can be positioned along the cavity waveguide.

During operation of a light source 10 constructed according to FIG. 9, the electronics can operate the tuner 519 associated with the first optical grating 516 and/or the tuner 519 associated with the second optical grating 520 such that one of the reflection bands from the first optical grating 516 overlaps with one of the reflection bands from the second optical grating 520. In order to provide chirp to the system output signal, the electronics can operate the phase shifter 514 so as to change the wavelength and/or frequency of the outgoing LIDAR signal, and accordingly of the system output signal. The wavelength and/or frequency of the outgoing LIDAR signal changes as a result of change of real part of refractive index of phase shifter 514 and/or imaginary part of refractive index of phase shifter 514. Additionally or alternately, chirp can be provided by operating the tuner 519 associated with the first optical grating 516 and/or the tuner 519 associated with the second optical grating 520 so as to change the overlapping reflection bands. Additionally or alternately, chirp can be provided by tuning the electrical current driven through the gain medium by the electronics. The electronics can employ one, two, or three mechanisms to tune the frequency of the system output signal so as to provide the system output signal with the desired chirp pattern where the mechanisms are selected from the group consisting of tuning the electrical current driven through the gain medium, changing the overlapping reflection bands, and tuning the phase shifter 514.

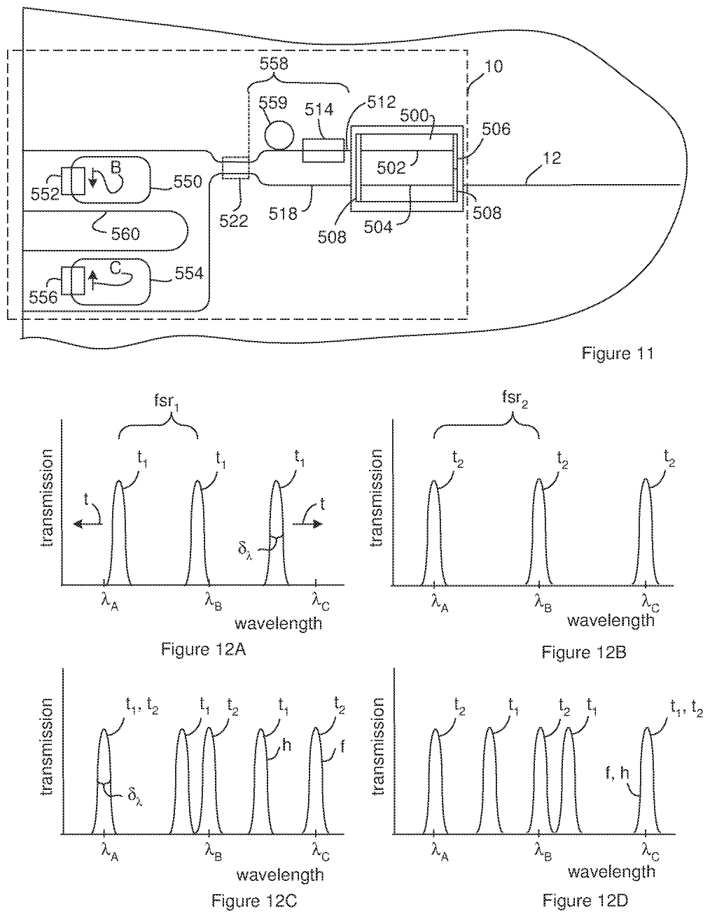

Another example of a light source has a laser cavity in which a light signal resonates along a pathway that includes waveguides and one or more tunable ring resonators. The tunable ring resonator couples light traveling one of the waveguides in multiple different transmission bands from the waveguide into the tunable ring resonator. In some instances, the pathway includes a second ring resonator that couples light traveling along one of the waveguides in multiple different second transmission bands from the waveguide into the second ring resonator. As an example, FIG. 11 is a schematic of a topview of a light source that with a laser cavity that has multiple ring resonators. The light source 10 includes a gain medium 500 for a laser. The gain medium 510 includes a laser waveguide 502 and an amplifier waveguide 504.

The light source 10 also includes a cavity waveguide 512. A phase shifter 514 is positioned along the cavity waveguide 512 such that the electronics can operate the phase shifter so as to tune the phase of a light signal guided in the cavity waveguide 512. A first ring resonator 550 is optically coupled with the cavity waveguide 512. The first ring resonator 550 includes a first tuner 552 that can be operated by the electronics so as to tune the free spectral range of resonance of the first ring resonator 550. The light source 10 includes an auxiliary waveguide 518. A second ring resonator 554 is optically coupled with the auxiliary waveguide 518. The second ring resonator 552 includes a second tuner 556 that can be operated by the electronics so as to tune the phase of a light signal carried in the second ring resonator 552.

The light source 10 also includes a transition waveguide 560 optically coupled with the cavity waveguide 512 and the auxiliary waveguide 518.

During operation of the light source, an electrical current is driven through the gain medium 500 so as to cause the gain medium 500 to output an output light signal on the laser waveguide 502. The output light signal passes through the anti-reflective coating 508. The laser waveguide 502 is aligned with the cavity waveguide 512 such that the cavity waveguide 512 receives the output light signal. The cavity waveguide 512 carries the output light signal to the optical coupler 520. The optical coupler 520 passes a first portion of the output light signal on the cavity waveguide 512 and moves a second portion of the output light signal onto the auxiliary waveguide 518. The portion of the output light signal moved onto the auxiliary waveguide 518 serves as a transferred signal and the portion of the output light signal passed to the cavity waveguide 512 serves as an outgoing passed signal.

The cavity waveguide 512 carries the outgoing passed signal to the first ring resonator 550. When the wavelength of the outgoing passed signal is in a transmission band of the first ring resonator 550, at least a portion of the outgoing passed signal is coupled from the cavity waveguide into the first ring resonator 550 such that the coupled portion of the output light signal travels in the direction of the arrow labeled B.

When the wavelength of the outgoing passed signal is within a transmission band of the first ring resonator 550, at least part of the outgoing passed signal is coupled from the first ring resonator 550 into the transition waveguide 560 as a transition signal. When the wavelength of the transition signal traveling along the transition waveguide 560 is within a transmission band of the second ring resonator 554, at least a portion of the transition signal is coupled from the transition waveguide 560 into the second ring resonator 554.

When the wavelength of the transition signal traveling in the second ring resonator 554 is within a transmission band of the second ring resonator 554, at least part of the coupled portion of the transition signal is coupled from the second ring resonator 554 into the auxiliary waveguide 518 where it serves as a second returned signal. The auxiliary waveguide 518 carries the second returned signal to the optical coupler 520. The optical coupler 520 passes a first portion of the second returned signal on the auxiliary waveguide 518 and moves a second portion of the second returned signal onto the cavity waveguide 512. The portion of the second returned signal moved onto the cavity waveguide 512 serves as a second transferred return signal. The portion of the first returned signal passed on the auxiliary waveguide 518 serves as a second passed return signal.

The auxiliary waveguide 518 carries the transferred signal to the second ring resonator 554. When the wavelength of the transferred signal traveling in the auxiliary waveguide 518 is within a transmission band of the second ring resonator 554, at least a portion of the transferred signal is coupled from the auxiliary waveguide 518 into the second ring resonator 554 such that the coupled portion of the transferred light signal travels in the direction of the arrow labeled C.

When the wavelength of the coupled portion of the transferred light signal traveling in the second ring resonator 554 is within a transmission band of the second ring resonator 554, at least part of the coupled portion of the transferred light signal is coupled from the second ring resonator 554 into the transition waveguide 560 as a second transition signal.

When the wavelength of the second transition signal traveling in the transition waveguide 560 is within a transmission band of the first ring resonator 550, at least a portion of the second transition signal is coupled from the first ring resonator 550 into the first ring resonator 550.

When the wavelength of the second transition signal traveling in the first ring resonator 550 is within a transmission band of the first ring resonator 550, at least part of the coupled portion of the second transition signal is coupled into the cavity waveguide 512 where it serves as a first returned signal.

The cavity waveguide 512 carries the first returned signal to the optical coupler 520. The optical coupler 520 passes a first portion of the first returned signal on the cavity waveguide 512 and moves a second portion of the first returned signal onto the auxiliary waveguide 518. The portion of the first returned signal moved onto the auxiliary waveguide 518 serves as a transferred return signal. The portion of the first returned signal passed on the cavity waveguide 512 serves as a passed return signal.

The optical coupler 520, the cavity waveguide 512, the first ring resonator 550, the transition waveguide 560, the second ring resonator 554, and the portion of the auxiliary waveguide 518 that carries light signals to and/or from the second ring resonator 554 to the optical coupler 520 can be part of an optical pathway along which light signal resonate in the laser cavity. The portion of the cavity waveguide 512 that carries light signals between the first ring resonator 550 and the optical coupler 520, optical coupler 520, the first ring resonator 550, the transition waveguide 560, the second ring resonator 554, and the portion of the auxiliary waveguide 518 that carries light signals between the second ring resonator 554 and the optical coupler 520 together form a loop in the optical pathway. The loop carries light signals to and from the portion of the cavity waveguide 512 that carries light signals between the optical coupler 520 and the gain medium 500 (the preliminary waveguide 558). The light signals travel both directions in the loop. The loop receives light signals from the preliminary waveguide 558 and returns them to the preliminary waveguide 558. As a result, the loop effectively serves as a reflector in the laser cavity. Accordingly, the laser cavity can be defined by the loop and the light signal can resonate between the loop and the reflective layer 506.

The unamplified output of the laser cavity exits the laser cavity through a port of the optical coupler 520. For instance, the combination of the transferred return signal and the second passed return signal serve as the unamplified output of the laser cavity. The auxiliary waveguide 518 carries the transferred return signal and the second passed return signal to the gain medium 500. The amplifier waveguide 504 is aligned with the auxiliary waveguide 518 such that at least a portion of the transferred return signal and at least a portion of the second passed return signal is received by the amplifier waveguide 504. The electrical current driven through the gain medium 500 amplifies the received portion of the transferred return signal and the second passed return signal such that the amplifier 510 outputs an amplified transferred return signal. Accordingly, the amplified transferred return signal include, consists of, or consists essentially of light from the transferred return signal and the second passed return signal. The utility waveguide 12 is aligned with the amplifier waveguide 504 such that at least a portion of the amplified transferred return signal is received by the utility waveguide 12. The portion of the amplified transferred return signal received by the utility waveguide 12 serves as the outgoing LIDAR signal.

The cavity waveguide in the above light sources can optionally include a delay segment. As an example, FIG. 11 illustrates a portion of the cavity waveguide 512 having a spiral configuration that serves as a delay segment 599. The delay segment can increase the length of the external portion of an external cavity laser and can accordingly decrease the linewidth of the outgoing LIDAR signal output from the light source. The reduction in the linewidth of the outgoing LIDAR signal output reduces the linewidth of the system output signal.

The first ring resonator 550 and/or the second ring resonator 554 can be tunable. For instance, FIG. 12A can be an example of a transmission profile for a ring resonator that can serve as the first ring resonator 550. The ring resonator optically couples different wavelengths of light to and/or from a waveguide at different intensities. In particular, the y-axis of FIG. 12A shows the intensity of light that the ring resonator optically couples to and/or from a waveguide at the wavelength shown on the x-axis. The y-axis of FIG. 12A can be units of intensity, percentages, or can be normalized.

As is evident in FIG. 12A, the transmission profile includes multiple peaks that each represents a transmission band. The transmission band occurs at the wavelengths that the ring resonator optically couples to and/or from a waveguide. Each of the transmission bands for the first ring resonator 550 are labeled t₁. The bandwidth of a transmission band can be a function of the full width half-maximum of the transmission band (δλ). The transmission bands have a maximum and the maxima are separated by the Free Spectral Range (FSR) of the ring resonator.

In FIG. 12A, the Free Spectral Range (FSR) of the first ring resonator 550 is represented by fsr₁. The first ring resonator 550 is configured such that the selection of wavelengths in each of the transmission bands can be tuned. For instance, the first ring resonator 550 can be associated with the first tuner 552. The first tuner 552 can be operated by the electronics so as to tune the selection of wavelengths in each of the transmission bands. For instance, the Free Spectral Range (FSR) of the first optical grating 516 as represented by fsr₁ can represent the Free Spectral Range (FSR) of the first optical grating 516 when the tuner is not operated by the electronics. The electronics can operate the first tuner 552 so as to shift the selection of wavelengths the transmission bands of FIG. 12A as illustrated by the arrow labeled t. Accordingly, the electronics can operate the tuner associated with the first ring resonator 550 so as to as to change the Free Spectral Range (FSR) of the first ring resonator 550 and/or shift the transmission bands to higher or lower wavelengths. As a result, the electronics can operate the first tuner 552 so as to change the wavelengths in each of the transmission bands.

In some instances, the second ring resonator 554 is configured such that the selection of wavelengths in each of the transmission bands can be tuned as described for the first ring resonator 550. For instance, the second tuner 556 can be operated by the electronics so as to tune the selection of wavelengths in each of the transmission bands. However, the second ring resonator 554 need not be associated with a tuner. For the purposes of illustration, FIG. 12B is an example transmission profile for a ring resonator that can serve as a second ring resonator 554 that is not associated with a tuner. The Free Spectral Range (FSR) of the second ring resonator 554 is represented by fsr₂. Each of the transmission bands for the second ring resonator 554 is labeled t₂. The transmission bands (t₂) have maxima at the wavelengths labeled λ_{A}, λ_{B}, and λ_{C}.

The wavelengths labeled λ_{A}, λ_{B}, and λ_{C} are also shown in FIG. 12A. In FIG. 12A, the transmission bands for the first ring resonator 550 are labeled t₁ and are not aligned with any of the wavelengths labeled λ_{A}, λ_{B}, and λ_{C}. FIG. 12C shows the transmission profiles for the first ring resonator 550 and the second ring resonator 554 on the same graph. The transmission bands (t₂) for the second ring resonator 554 have maxima at the wavelengths labeled λ_{A}, λ_{B}, and λ_{C} as shown in FIG. 12B. However, the first ring resonator 550 has been tuned such that one of the transmission bands (t₁) for the first ring resonator 550 is positioned at the wavelength labeled λ_{A}. When a transmission band (t₁) for the first ring resonator 550 and a transmission band (t₂) for the second ring resonator 554 share a wavelength(s), the light source lases and provides an output at the shared wavelength(s). Accordingly, the unamplified output of the laser cavity and the amplified output of the laser cavity include, consist of, or consist essentially of light of the shared wavelength(s). In the case of FIG. 12C, the unamplified output of the laser cavity and the amplified output of the laser cavity include, consist of, or consist essentially of wavelength(s) within the transmission band that includes Xi.

As is evident from FIG. 12C, the free spectral range of the second ring resonator 554 is different from the free spectral range of the first ring resonator 550. The free spectral ranges are selected such that a transmission bands (t₁) for the first ring resonator 550 can share wavelength with a transmission band (t₂) for the second ring resonator 554 without the remaining transmission bands (t₂) from the second ring resonator 554 sharing wavelength with any transmission bands (t₁) for the first ring resonator 550. For instance, FIG. 12C shows overlap between a transmission band (t₂) from the second ring resonator 554 and a transmission band (t₁) for the first ring resonator 550 without any overlap between the remaining transmission bands. This arrangement is a result of the difference between the free spectral range of the second ring resonator 554 and the free spectral range of the first ring resonator 550. In some instances, the free spectral range of the second ring resonator 554 is within the free spectral range of the first ring resonator 550+/−an amount that less than 10% of free spectral range of the first ring resonator 550, an amount that less than 6% of free spectral range of the first ring resonator 550, or an amount that less than 2% of free spectral range of the first ring resonator 550.

In some instances, the first ring resonator 550 and/or the second ring resonator 554 are tuned such that the full width half-maximum (δλ) of a transmission band (t₂) from the second ring resonator 554 shares more than 10%, 20%, or 50% of the wavelengths with the full width half-maximum (δλ) of a transmission band (t₁) from the first ring resonator 550. In FIG. 12C, the first ring resonator 550 is tuned such that the full width half-maximum (δλ) of a transmission band (t₂) from the second ring resonator 554 shares 100% of the wavelengths with the full width half-maximum (δλ) of a transmission band (t₁) from the first ring resonator 550.

The first ring resonator 550 and/or the second ring resonator 554 can be tuned such that multiple different selections of transmission bands can overlap. For instance, FIG. 12D illustrates the results of tuning the first ring resonator 550 and/or the second ring resonator 554 of FIG. 12C such that the transmission band labeled h in FIG. 12C overlaps the transmission band labeled fin FIG. 12C. As a result, FIG. 12D illustrates different transmission bands overlapping than are overlapped in FIG. 12C.

In some instances, the first ring resonator 550 and the second ring resonator 554 are switched. Accordingly, the first ring resonator 550 can be optically coupled with the auxiliary waveguide 518 and the transition waveguide and the second optical grating 520 can be optically coupled with the cavity waveguide 512 and the transition waveguide.

During operation of the light sources 10 illustrated in FIG. 11 through FIG. 12D, the electronics can operate the first tuner 552 and/or the second tuner 556 such that one of the transmission bands from the first ring resonator 550 fully or partially overlaps with one of the transmission bands from the second ring resonator 554. In order to provide chirp to the system output signal, the electronics can operate the phase shifter 514 so as to change the wavelength and/or frequency of the outgoing LIDAR signal, and accordingly of the system output signal. The wavelength and/or frequency of the outgoing LIDAR signal changes as a result of a change in the refractive index of phase shifter 514 (the real part of refractive index of phase shifter 514 and/or imaginary part of refractive index of phase shifter 514). Additionally or alternately, chirp can be provided by operating the first tuner 552 and/or the second tuner 556 so as to change the overlapping transmission bands. Additionally or alternately, chirp can be provided by tuning the electrical current driven through the gain medium by the electronics. The electronics can employ one, two, or three mechanisms to tune the frequency of the system output signal so as to provide the system output signal with the desired chirp pattern where the mechanisms are selected from the group consisting of tuning the electrical current driven through the gain medium, changing the overlapping transmission bands, and tuning the phase shifter 514.

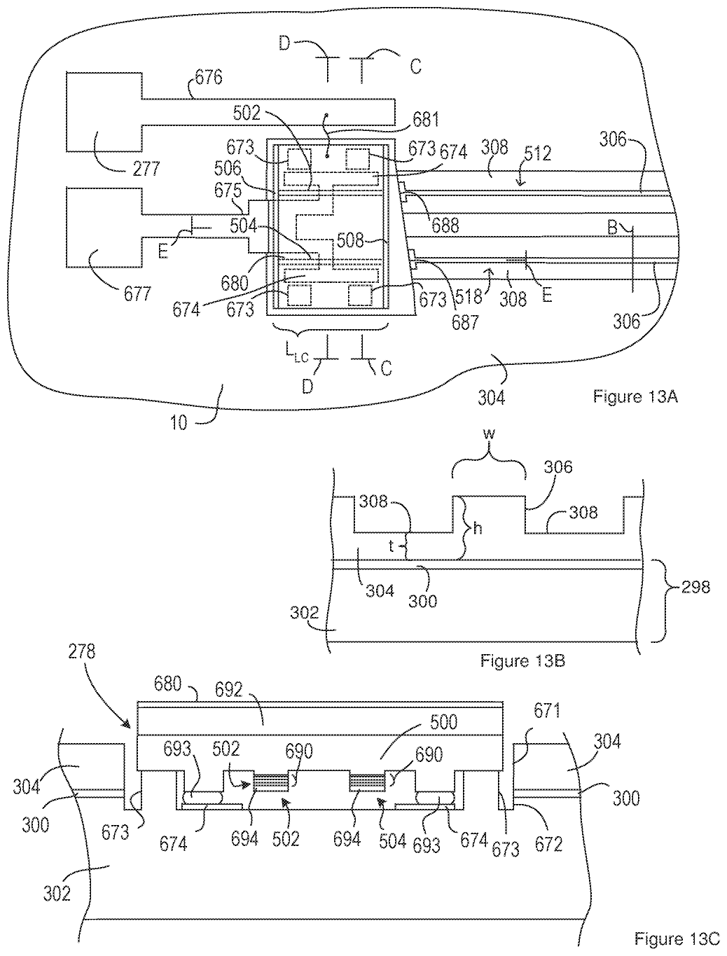

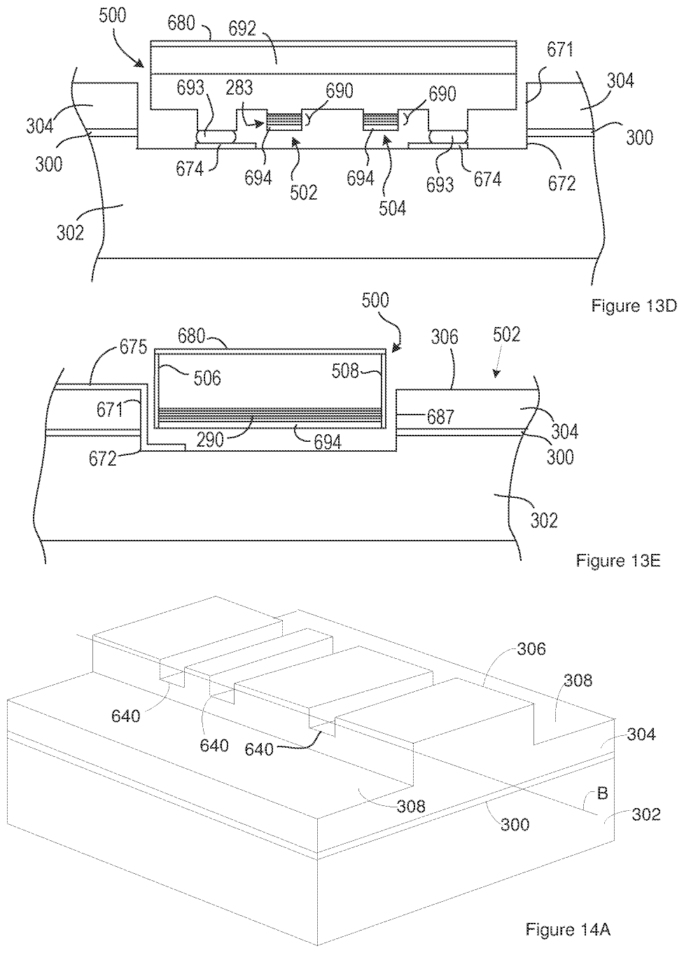

FIG. 13A through FIG. 13D illustrates an example of an interface between a gain medium chip and a platform such as a silicon-on-insulator chip. FIG. 13A is a topview of the light source. FIG. 13A includes dashed lines that each illustrates a component or a portion of a component that is located beneath other components that are illustrated by solid lines. The relationship between of the components illustrated by the dashed lines in FIG. 13A and the other components are also shown in FIG. 13B through FIG. 13E. FIG. 13B is a cross section of the interface shown in FIG. 13A taken along the line labeled B. The line labeled B extends through the cavity waveguide 512. Accordingly, FIG. 13B includes a cross section of the cavity waveguide 512. FIG. 13C is a cross section of the interface taken along a line extending between the brackets labeled C in FIG. 13A. FIG. 13C is a cross section of the interface taken along a line extending between the brackets labeled C in FIG. 13A. FIG. 13D is a cross section of the interface taken along a line extending between the brackets labeled D in FIG. 13A. FIG. 13E is a cross section of the interface of FIG. 13A taken along a line extending between the brackets labeled D in FIG. 13A. The interface is illustrated as being on a silicon-on-insulator platform although other platforms are possible.

A first recess 671 extends into or through the light-transmitting medium 304. In some instances where the first recess 671 extends through the light-transmitting medium 304, the first recess 671 can extend into or through the buried layer 300. A second recess 672 extends into the bottom of the first recess 671 such that the substrate 302 includes pillars 673 extending upward from the bottom of the second recess 672. Electrical contacts 674 are positioned in the bottom of the second recess 672. A first conductor 675 on the light-transmitting medium 304 is in electrical communication with the electrical contacts 674. A second conductor 676 on the light-transmitting medium 304 is positioned adjacent to the first recess 671. The first conductor 675 and the second conductor 676 are each in electrical communication with a contact pad 677 on the light-transmitting medium 304. The contact pads 677 can be used to provide electrical communication between electronics and the gain medium 500.

A gain medium chip includes the gain medium 500 and is positioned in the first recess 671 and on the pillars 673. The gain medium chip can be attached to a platform such as a silicon-on-insulator platform using flip-chip technologies. Examples of suitable interfaces between a gain medium chip and a platform such as a silicon-on-insulator platform can be found in U.S. Pat. No. 9,705,278, issued on Jul. 11, 2017, and in U.S. Pat. No. 5,991,484 issued on Nov. 23, 1999; each of which is incorporated herein in its entirety.

The reflective layer 506 and the anti-reflective coating 508 are each positioned on a facet of the gain medium 500. A second conducting layer 680 is positioned on the gain medium 500. A third conductor 681 provides electrical communication between the second conducting layer 680 and the second conductor 676.

The gain medium chip includes four ridges that extend into the second recess 672. One of the central ridges defines a portion of the laser waveguide 502 and another of the central ridges defines a portion of the amplifier waveguide 504. The outer ridges are each in electrical communication with one of the electrical contacts 674 through a conducting medium 693 such as solder or conducting epoxy. Since the first conductor 675 is in electrical communication with the electrical contacts 674, the first conductor 675 is in electrical communication with the outer ridges.

The light signal can be generated from the gain medium 500 by driving an electrical current through the gain medium 500. The electrical current can be generated by applying a potential difference between the first conductor 675 and the second conductor 676. The potential difference can be provided by the electronics. The electronics can be included on the device or can be separate from the device but electrically coupled with the device.

The gain medium 500 includes sub-layers 690 between a lower gain medium 692 and an upper gain medium 694. The lower gain medium 692 and the upper gain medium 694 can be the same or different. Suitable lower gain media 692 include, but are not limited to, InP, doped InP, gallium nitride (GaN), InGaAsP, and GaAs. Suitable upper gain media 694 include, but are not limited to, InP, InGaAsP, and GaAs. Different sub-layers 690 can have different compositions. For instance, each sub-layer 690 can have a different dopant and/or dopant concentration from the one or more neighboring sub-layers 690 and/or each of the sub-layers 690 can have a different dopant and/or dopant concentration. As an example, each sub-layer 690 can include or consists of two or more components selected from a group consisting of In, P, Ga, and As and different sub-layers 690 can have the elements present in different ratios. In another example, each sub-layer 690 includes or consists In, P and none, one, or two components selected from a group consisting of Al, Ga, and As and each of the different sub-layers 690 has these components in a different ratio. Examples of materials that include multiple elements selected from the above group include different compositions of InP with or without dopants such as In(x)P(1−x) or In—Ga—As—P. Additionally, there may be other sub-layers 690 present to compensate for stress due to lattice mismatch between the compositions of the different sub-layers 690. The location of the laser mode in the laser ridge is defined by the different sub-layers 690 as a result of the refractive indices of the different compositions.

The electrical communication between the second conducting layer 680 and the second conductor 676 provided by the third conductor 681 can be achieved using traditional techniques such as wire bonding.

The gain medium chip is arranged such that the laser waveguide 502 is aligned with the cavity waveguide 512 such that the cavity waveguide 512 receives the light signal output from the waveguide 502 through an input facet 687 and the amplifier waveguide 504 is aligned with the auxiliary waveguide 518 such that the amplifier waveguide 504 receives at least a portion of the transferred return signal and at least a portion of the second passed return signal from the auxiliary waveguide 518 through an input facet 688. Although not illustrated, the input facet 687 and/or the input facet 687 can optionally include one or more anti-reflective coatings such as silicon nitride. The space between the input facet 687 and the gain medium chip can be filled with a transmitting medium that is a solid or a fluid. For instance, the space between the anti-reflective coating 508 and the input facet 287 and/or the input facet 288 can be filled with an epoxy, air, or gel. As a result, light signal can travel between the gain medium chip and the input facet 287 and/or between the gain medium chip and the input facet 288 through the transmissive medium.

The input facet 287 and/or input facet 287 can be angled at less than ninety degrees relative to the direction of propagation in the associated waveguide. Angling the input facet 287 and/or input facet 287 at less than ninety degrees can cause light signals reflected at the input facet 287 and/or input facet 287 to be reflected out of the associated waveguide(s) and can accordingly reduce issues associated with back reflection. Additionally or alternately, a facet of the laser waveguide 502 and/or amplifier waveguide 504 can be angled at less than ninety degrees relative to the direction of propagation in the associated waveguide(s).

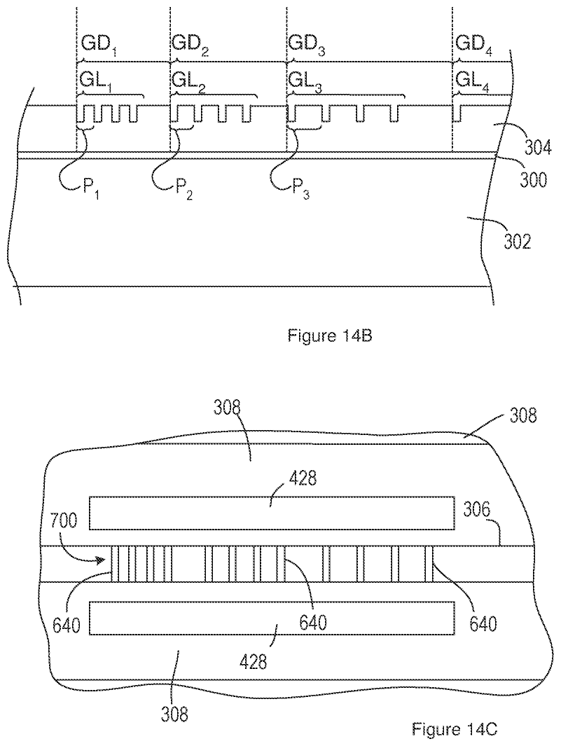

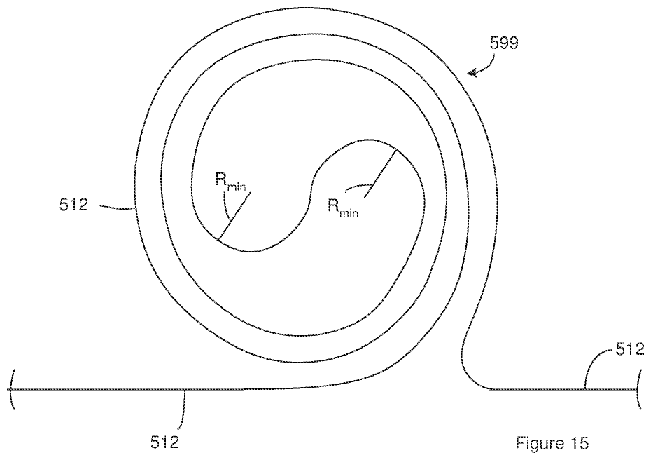

FIG. 14A is a perspective view of an optical grating that is suitable for use as the first optical grating 516 and/or the second optical grating 520. A ridge 306 of the light-transmitting medium extends away from slab regions 308 of the light-transmitting medium. Recesses 640 extend into the top of the ridge 306. The recesses 640 are filled with a medium having a lower index of refraction than the light-transmitting medium 304. The medium can be a solid or a gas such as air. Accordingly, the recesses 640 provide perturbations in the effective refractive index of the light-transmitting medium 304. The recesses 640 can be formed with photolithography combined with etching technologies such as wet etching and dry etching. Although the recesses 640 are shown in the top of the ridge, the recesses 640 can be in the side of the ridge and/or into the slab regions 308 next to the ridge 306.

The first optical grating 516 and/or the second optical grating 520 can be configured as a sampled grating or a superstructured grating. As an example, FIG. 14B is a cross section of the optical grating shown in FIG. 14A taken along the line labeled B in FIG. 14A. The grating includes M grating segments. Each grating section is associated with a section index m that extends from m=1 to M. Each grating section has a length labeled GDₘ. Additionally, each grating section includes a grating sub-section with a length labeled GLₘ. The perturbation regions in a grating sub-section are arranged with a pitch labeled Pₘ. An auxiliary portion of each grating section excludes perturbation regions and has a length of GDₘ−GLₘ. In a sampled grating, the grating section lengths (GDₘ) are different, the grating sub-section lengths (GLₘ) can be the same or different and are selected to provide the desired free spectral range, and the pitches (Pₘ) are the same or substantially the same. In some embodiments, a sampled grating has a number of grating segments greater than or equal to 10, 20, or 30 and/or less than or equal to 50, 70, or 100; the grating segments each include a number of perturbation structures greater than or equal to 100, 200, or 300 and/or less than or equal to 500, 600, or 800; the perturbation regions in a grating sub-section are arranged with a half pitch greater than or equal to 110 nm, 111 nm, or 112 nm and/or less than or equal to 113 nm, 114 nm, or 115 nm; and the grating sub-section lengths (GLₘ) are greater than or equal to 10 um, 20 um, or 30 um and/or less than or equal to 50 um, 60 um, or 80 um

A superstructured grating excludes the auxiliary portions between grating subsections. Accordingly, a superstructured grating is configured such that GDₘ=GLₘ. Additionally, in a superstructured grating, the grating sub-section lengths (GLₘ) can be the same or different and are selected to provide the desired free spectral range, and the pitches (Pₘ) are different. In some embodiments, a superstructured grating has a number of grating segments greater than or equal to 3, 5, or 7 and/or less than or equal to 10, 15, or 20; the grating segments each include a number of perturbation structures greater than or equal to 100, 200, or 300 and/or less than or equal to 500, 600, or 1000; the perturbation regions in each grating sub-section are arranged with a half pitch greater than or equal to 110 nm, 111 nm, or 112 nm and/or less than or equal to 113 nm, 114 nm, or 115 nm; and the grating sub-section lengths (GLₘ) are greater than or equal to 10 um, 20 um, or 30 um and/or less than or equal to 50 um, 60 um, or 80 um.

A variety of electro-optical component structures are suitable for use as the first tuner 552, the second tuner 556, one or more of the tuners 519, and the phase shifter 514. Suitable electro-optical components include electro-optical tuners that can be operated by the electronics so as to tune the index of refraction of at least a portion of a waveguide with which the electro-optical tuner is associated. For instance, components such as phase shifters, PIN carrier injection devices, heaters, and carrier depletion devices can serve as a suitable electro-optical tuner. As an example, one or more electro-optical components selected from the group consisting of the first tuner 552, the second tuner 556, one or more of the tuners 519, and the phase shifter 514 can be constructed as disclosed in the context of FIG. 5B. As a result, the branch waveguides 418 shown in FIG. 5B can represent a cavity waveguide 512, an auxiliary waveguide 518, a waveguide that serves as the first ring resonator 550, or a waveguide that serves as the second ring resonator 554. As an example, FIG. 14C is a topview of a portion of cavity waveguide 512 or an auxiliary waveguide 518 that includes an optical grating 700 that can serve as a first optical grating 516 or a second optical grating 520. The optical grating 700 is associated with a tuner 519 constructed according to FIG. 5B. For the purposes of simplification, the first cladding 430, second cladding 432, and conductors 424 shown in FIG. 5B are not illustrated in FIG. 14C so the underlying doped regions 428 are visible. As a result, the relationship between the doped regions 428 and optical grating 700 are visible in FIG. 14C. An electro-optical component constructed according to FIG. 5B can serve as a phase shifter, a variable optical attenuator, and/or a modulator.

FIG. 15 is a topview of a portion of a cavity waveguide 512 that includes a delay segment 599. The delay segment 599 has a spiral arrangement. Near the center of the spiral arrangement, the cavity waveguide 512 turns back upon itself. The spiral configuration is selected such that the portion of the waveguide with the smallest radius of curvature (labeled Rₘᵢₙ) has a radius of curvature above a curvature threshold. Suitable curvature thresholds include, but are not limited to, curvature thresholds above or equal to 0.025 mm, 0.1 mm, and 0.3 mm. Although the spiral arrangement is shown in a geometry that approximates a circle, the spiral arrangement can be in other geometries such as shapes that approximate an oval, rectangle or triangle. As a result, the spiral arrangement can include straight waveguide segments and/or substantially straight waveguide segments.

Light sensors that are interfaced with waveguides on a LIDAR chip can be a component that is separate from the chip and then attached to the chip. For instance, the light sensor can be a photodiode, or an avalanche photodiode. Examples of suitable light sensor components include, but are not limited to, InGaAs PIN photodiodes manufactured by Hamamatsu located in Hamamatsu City, Japan, or an InGaAs APD (Avalanche Photo Diode) manufactured by Hamamatsu located in Hamamatsu City, Japan. These light sensors can be centrally located on the LIDAR chip. Alternately, all or a portion the waveguides that terminate at a light sensor can terminate at a facet located at an edge of the chip and the light sensor can be attached to the edge of the chip over the facet such that the light sensor receives light that passes through the facet. The use of light sensors that are a separate component from the chip is suitable for all or a portion of the light sensors selected from the group consisting of the first light sensor and the second light sensor.

As an alternative to a light sensor that is a separate component, all or a portion of the light sensors can be integrated with the chip. For instance, examples of light sensors that are interfaced with ridge waveguides on a chip constructed from a silicon-on-insulator wafer can be found in Optics Express Vol. 15, No. 21, 13965-13971 (2007); U.S. Pat. No. 8,093,080, issued on Jan. 10 2012; U.S. Pat. No. 8,242,432, issued Aug. 14 2012; and U.S. Pat. No. 6,108,8472, issued on Aug. 22, 2000 each of which is incorporated herein in its entirety. The use of light sensors that are integrated with the chip are suitable for all or a portion of the light sensors selected from the group consisting of the first light sensor and the second light sensor.

Suitable electronics 62 for use in the LIDAR system can include, but are not limited to, a controller that includes or consists of analog electrical circuits, digital electrical circuits, processors, microprocessors, digital signal processors (DSPs), Application Specific Integrated Circuits (ASICs), computers, microcomputers, or combinations suitable for performing the operation, monitoring and control functions described above. In some instances, the controller has access to a memory that includes instructions to be executed by the controller during performance of the operation, control and monitoring functions. Although the electronics are illustrated as a single component in a single location, the electronics can include multiple different components that are independent of one another and/or placed in different locations. Additionally, as noted above, all or a portion of the disclosed electronics can be included on the chip including electronics that are integrated with the chip.

Components on the LIDAR chip can be fully or partially integrated with the LIDAR chip. For instance, the integrated optical components can include or consist of a portion of the wafer from which the LIDAR chip is fabricated. A wafer that can serve as a platform for a LIDAR chip can include multiple layers of material. At least a portion of the different layers can be different materials. As an example, in a silicon-on-insulator wafer that includes the buried layer 300 between the substrate 302 and the light-transmitting medium 304 as shown in FIG. 4, the integrated on-chip components can be formed by using etching and masking techniques to define the features of the component in the light-transmitting medium 304. For instance, the slab regions 308 that define the waveguides and the stop recess can be formed in the desired regions of the wafer using different etches of the wafer. As a result, the LIDAR chip includes a portion of the wafer and the integrated on-chip components can each include or consist of a portion of the wafer. Further, the integrated on-chip components can be configured such that light signals traveling through the component travel through one or more of the layers that were originally included in the wafer. For instance, the waveguide of FIG. 4 guides light signal through the light-transmitting medium 304 from the wafer. The integrated components can optionally include materials in addition to the materials that were present on the wafer. For instance, the integrated components can include reflective materials and/or a cladding.

Although the gain medium is disclosed as having both a laser waveguide and an amplifier waveguide, the amplifier waveguide is optional. As a result, the utility waveguide can be continuous with the auxiliary waveguide and/or can serve the auxiliary waveguide.

Numeric labels such as first, second, third, etc. are used to distinguish different features and components and do not indicate sequence or existence of lower numbered features. For instance, a second component can exist without the presence of a first component and/or a third step can be performed before a first step. The light signals disclosed above each include, consist of, or consist essentially of light from the prior light signal(s) from which the light signal is derived. For instance, an incoming LIDAR signal includes, consists of, or consists essentially of light from the LIDAR input signal.

Although the LIDAR system is disclosed as using complex signals such as the complex data signal, the LIDAR system can also use real signals. As a result, the mathematical transform can be a real transform and the components associated with the generation and use of the quadrature components can be removed from the LIDAR system. As a result, the LIDAR system can use a single signal combiner. Additionally or alternately, a single light sensor can replace each of the balanced detectors.

Other embodiments, combinations and modifications of this invention will occur readily to those of ordinary skill in the art in view of these teachings. Therefore, this invention is to be limited only by the following claims, which include all such embodiments and modifications when viewed in conjunction with the above specification and accompanying drawings.

1. An imaging system, comprising:
an external cavity laser having a laser cavity that is partially defined by a tunable optical grating, the tunable optical grating configured to reflect light signals in multiple different reflection bands; and
electronics configured to tune the optical grating such wavelengths of light in the reflection bands changes in response to the tuning.

2. The system of claim 1, wherein the tunable optical grating is a Bragg reflector.

3. The system of claim 1, wherein the external cavity laser is partially defined by a second optical grating.

4. The system of claim 3, wherein the light signal resonates between a reflective surface and the tunable optical grating and also resonates between the reflective surface and the second optical grating.

5. The system of claim 3, wherein the second optical grating is configured to reflect light signals in multiple different second reflection bands.

6. The system of claim 5, wherein the second optical grating is tunable.

7. The system of claim 6, wherein the electronics are configured to tune the second optical grating such wavelengths of light in the second reflection bands changes in response to the tuning.

8. The system of claim 7, wherein the light signal resonates between a reflective surface and the tunable optical grating and also resonates between the reflective surface and the second optical grating.

9. The system of claim 1, wherein the laser cavity includes a phase tuner operated by the electronics so as to tune a phase of a light signal resonating in the laser cavity such that a frequency of an output from the laser cavity changes in response to the tuning of the phase tuner.

10. The system of claim 9, wherein the output from the laser cavity has wavelengths that are shared by one of the reflection bands and one of the second reflection bands.

11. An imaging system, comprising:
an external cavity laser having a laser cavity in which a light signal resonates along a pathway, the pathway including waveguides and a tunable ring resonator, the tunable ring resonator configured to couple light traveling along one of the waveguides in multiple different transmission bands from the waveguide into the tunable ring resonator; and
electronics configured to tune the tunable ring resonator such wavelengths of light in the transmission bands changes in response to the tuning.

12. The system of claim 11, wherein the pathway that includes a second ring resonator configured to couple light traveling along one of the waveguides in multiple different second transmission bands from the waveguide into the second tunable ring resonator.

13. The system of claim 11, wherein the second ring resonator is tunable.

14. The system of claim 13, wherein the electronics are configured to tune the second ring resonator such wavelengths of light in the second transmission bands changes in response to the tuning.

15. The system of claim 11, wherein the laser cavity includes a phase tuner operated by the electronics so as to tune a phase of a light signal resonating in the laser cavity such that a frequency of an output from the laser cavity changes in response to the tuning of the phase tuner.

16. The system of claim 11, wherein the laser cavity includes a phase tuner operated by the electronics so as to tune a phase of a light signal resonating in the laser cavity such that a frequency of an output from the laser cavity changes in response to the tuning of the phase tuner.

17. The system of claim 14, wherein the output from the laser cavity has wavelengths that are shared by one of the transmission bands and one of the second transmission bands.
